(19) United States
(12) Patent Application Publication
(10) Pub. No.: US 2022/0223813 A1
(43) Pub. Date: Jul. 14, 2022

(54) Light-Emitting Device, Light-Emitting Apparatus, Light-Emitting Module, Electronic Device, and Lighting Device

(71) Applicant: Semiconductor Energy Laboratory Co., Ltd., Kanagawa-ken (JP)

(72) Inventors: Airi Ueda, Sagamihara, Kanagawa (JP); Takeyoshi WATABE, Atsugi, Kanagawa (JP); Nobuharu OHSAWA, Zama, Kanagawa (JP); Satoshi SEO, Sagamihara, Kanagawa (JP)

(73) Assignee: Semiconductor Energy Laboratory Co., Ltd., Kanagawa-ken (JP)

(21) Appl. No.: 17/613,155

(22) PCT Filed: May 18, 2020
(86) PCT No.: PCT/IB2020/054668

§ 371 Date: Nov. 22, 2021

(30) Foreign Application Priority Data
May 31, 2019 (JP) 2019-102037

(51) Int. Cl. H01L 51/50

(52) U.S. Cl. CPC H01L 51/5012; H01L 27/3246

(57) ABSTRACT

A light-emitting device that emits both near-infrared light and visible light is provided. The light-emitting device includes a light-emitting organic compound and a host material in a light-emitting layer. The maximum peak wavelength in an emission spectrum of the light-emitting device is greater than or equal to 750 nm and less than or equal to 900 nm, the energy of the maximum peak in the emission spectrum of the host material is higher than the energy of a peak of a lowest-energy-side absorption band in an absorption spectrum of the light-emitting organic compound. The light-emitting device has a function of emitting both visible light and near-infrared light.

### TECHNICAL FIELD

One embodiment of the present invention relates to a light-emitting device, a light-emitting apparatus, a light-emitting module, an electronic device, and a lighting device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a driving method thereof, and a manufacturing method thereof.

### BACKGROUND ART

Research and development has been actively conducted on light-emitting devices using organic electroluminescence (EL) phenomenon (also referred to as organic EL devices or organic EL elements). In a basic structure of an organic EL device, a layer including a light-emitting organic compound (hereinafter also referred to as a light-emitting layer) is sandwiched between a pair of electrodes. By application of voltage to the organic EL device, light emitted from the light-emitting organic compound can be obtained.

An example of the light-emitting organic compound is a compound capable of converting a triplet excited state into light (also referred to as a phosphorescent compound or a phosphorescent material). As a phosphorescent material, Patent Document 1 discloses an organometallic complex that contains iridium or the like as a central metal.

Image sensors have been used in a variety of applications such as personal authentication, defect analysis, medical diagnosis, and security. The wavelength of light sources used for image sensors is different depending on applications. Light having a variety of wavelengths, for example, light having a short wavelength, such as visible light and X-rays, and light having a long wavelength, such as near-infrared light, is used for image sensors.

Light-emitting devices have been considered to be applied to light sources of image sensors such as the above in addition to display apparatuses.

### REFERENCE

### Patent Document

[Patent Document 1] Japanese Published Patent Application No. 2007-137872

### SUMMARY OF THE INVENTION

### Problems to be Solved by the Invention

An object of one embodiment of the present invention is to provide a light-emitting device that emits both near-infrared light and visible light. An object of one embodiment of the present invention is to enhance the emission efficiency of a light-emitting device that emits both near-infrared light and visible light. An object of one embodiment of the present invention is to enhance the reliability of a light-emitting device that emits both near-infrared light and visible light.

Note that the description of these objects does not preclude the existence of other objects. One embodiment of the present invention does not need to achieve all the objects. Other objects can be derived from the description of the specification, the drawings, and the claims.

### Means for Solving the Problems

One embodiment of the present invention is a light-emitting device including a light-emitting organic compound and a host material in a light-emitting layer, in which the maximum peak wavelength in an emission spectrum is greater than or equal to 750 nm and less than or equal to 900 nm, the emission spectrum further has a peak at greater than or equal to 450 nm and less than or equal to 650 nm, and a luminance A [cd/m²] and a radiance B [W/sr/m²] satisfy AB≥0.1 [cd·sr/W].

The difference between the HOMO level and the LUMO level of the host material is preferably greater than or equal to 1.90 eV and less than or equal to 2.75 eV, preferably greater than or equal to 2.25 eV and 2.75 eV. The difference between a singlet excitation energy level and a triplet excitation energy level of the host material is preferably less than or equal to 0.2 eV. The host material preferably exhibits thermally activated delayed fluorescence.

The host material preferably contains a first organic compound and a second organic compound. The HOMO level of the first organic compound is preferably higher than the HOMO level of the second organic compound. The difference between the HOMO level of the first organic compound and the LUMO level of the second organic compound is preferably greater than or equal to 1.90 eV and less than or equal to 2.75 eV, preferably greater than or equal to 2.25 eV and 2.75 eV. The first organic compound and the second organic compound preferably are substances forming an exciplex. The exciplex preferably exhibits thermally activated delayed fluorescence.

One embodiment of the present invention is a light-emitting device including a light-emitting organic compound and a host material in a light-emitting layer, in which the maximum peak wavelength in the emission spectrum is greater than or equal to 750 nm and less than or equal to 900 nm, and the energy of the maximum peak in a PL spectrum of the host material is higher than the energy of a peak of a lowest-energy-side absorption band in an absorption spectrum of the light-emitting organic compound by 0.20 eV or more. The light-emitting device has a function of emitting both visible light and near-infrared light. The energy of the maximum peak in the PL spectrum is preferably higher than the energy of a lowest-energy-side absorption edge in the absorption spectrum by 0.30 eV or more.

One embodiment of the present invention is a light-emitting device including a light-emitting organic compound and a host material in a light-emitting layer, in which the emission spectrum has a first peak at greater than or equal to 750 nm and less than or equal to 900 nm and has a second peak at greater than or equal to 450 nm and less than or equal to 650 nm, the first peak has higher intensity than the second peak, and the energy of the second peak is higher than the energy of a peak of a lowest-energy-side absorption band in an absorption spectrum of the light-emitting organic compound by 0.35 eV or more. The intensity of the first peak is preferably greater than or equal to 10 times and less than or equal to 10000 times the intensity of the second peak.

The difference between the HOMO level and the LUMO level of the host material is preferably greater than or equal to 1.90 eV and less than or equal to 2.75 eV, preferably greater than or equal to 2.25 eV and 2.75 eV.

The difference between a singlet excitation energy level and a triplet excitation energy level of the host material is preferably less than or equal to 0.2 eV.

The host material preferably exhibits thermally activated delayed fluorescence.

One embodiment of the present invention is a light-emitting device including a light-emitting organic compound and a host material in a light-emitting layer, in which the maximum peak wavelength in the emission spectrum is greater than or equal to 750 nm and less than or equal to 900 nm, the host material contains a first organic compound and a second organic compound, the first organic compound and the second organic compound are substances forming an exciplex, and the energy of the maximum peak in a PL spectrum of the exciplex is higher than the energy of a peak of a lowest-energy-side absorption band in an absorption spectrum of the light-emitting organic compound by 0.20 eV or more. The light-emitting device has a function of emitting both visible light and near-infrared light. The energy of the maximum peak in the PL spectrum is preferably higher than the energy of the peak of the lowest-energy-side absorption band in the absorption spectrum by 0.30 eV or more.

One embodiment of the present invention is a light-emitting device including a light-emitting organic compound and a host material in a light-emitting layer, in which the host material contains a first organic compound and a second organic compound, the first organic compound and the second organic compound are substances forming an exciplex, the emission spectrum has a first peak at greater than or equal to 750 nm and less than or equal to 900 nm and has a second peak at greater than or equal to 450 nm and less than or equal to 650 nm, the first peak has higher intensity than the second peak, and the energy of the second peak is higher than the energy of a peak of a lowest-energy-side absorption band in an absorption spectrum of the light-emitting organic compound by 0.35 eV or more. The intensity of the first peak is preferably greater than or equal to 10 times and less than or equal to 10000 times the intensity of the second peak.

The HOMO level of the first organic compound is preferably higher than the HOMO level of the second organic compound. The difference between the HOMO level of the first organic compound and the LUMO level of the second organic compound is preferably greater than or equal to 1.90 eV and less than or equal to 2.75 eV, preferably greater than or equal to 2.25 eV and 2.75 eV.

The concentration of the light-emitting compound in the light-emitting layer is preferably greater than or equal to 0.1 wt % and less than or equal to 10 wt %, further preferably greater than or equal to 0.1 wt % and less than or equal to 5 wt %.

A rising wavelength of the maximum peak on a short wavelength side in the emission spectrum is preferably greater than or equal to 650 nm.

A rising wavelength of the maximum peak on a short wavelength side in a PL spectrum of the light-emitting organic compound in a solution is preferably greater than or equal to 650 nm.

The external quantum efficiency of the light-emitting device is preferably greater than or equal to 1%. In particular, external quantum efficiency calculated from light emitted by the light-emitting organic compound is preferably greater than or equal to 1%.

In the light-emitting device, CIE chromaticity coordinates (x1, y1) at first radiance and CIE chromaticity coordinates (x2, y2) at second radiance preferably satisfy one or both of x1>x2 and y1>y2, where the first radiance is lower than the second radiance.

The light-emitting organic compound is preferably an organometallic complex having a metal-carbon bond.

The organometallic complex preferably includes a condensed heteroaromatic ring including 2 to 5 rings. The condensed heteroaromatic ring is preferably coordinated to metal.

The light-emitting organic compound is preferably a cyclometalated complex. The light-emitting organic compound is preferably an orthometalated complex. The light-emitting organic compound is preferably an iridium complex.

One embodiment of the present invention is a light-emitting apparatus that includes the light-emitting device having any of the above-described structures, and one or both of a transistor and a substrate.

One embodiment of the present invention is a light-emitting module including the above-described light-emitting apparatus, where a connector such as a flexible printed circuit (hereinafter referred to as FPC) or a TCP (Tape Carrier Package) is attached or an integrated circuit (IC) is mounted by a COG (Chip On Glass) method, a COF (Chip On Film) method, or the like. Note that the light-emitting module of one embodiment of the present invention may include only one of a connector and an IC or may include both of them.

One embodiment of the present invention is an electronic device including the above-described light-emitting module and at least one of an antenna, a battery, a housing, a camera, a speaker, a microphone, and an operation button.

One embodiment of the present invention is a lighting apparatus including the above-described light-emitting apparatus and at least one of a housing, a cover, and a supporting base.

### Effect of the Invention

According to one embodiment of the present invention, a light-emitting device that emits both near-infrared light and visible light can be provided. According to one embodiment of the present invention, the emission efficiency of a light-emitting device that emits both near-infrared light and visible light can be enhanced. According to one embodiment of the present invention, the reliability of a light-emitting device that emits both near-infrared light and visible light can be enhanced.

Note that the description of these effects does not preclude the existence of other effects. One embodiment of the present invention does not need to have all these effects. Other effects can be derived from the description of the specification, the drawings, and the claims.

### BRIEF DESCRIPTION OF THE DRAWINGS

FIG. 1A to FIG. 1C are diagrams illustrating examples of a light-emitting device.

FIG. 2A is a top view illustrating an example of a light-emitting apparatus. FIG. 2B and FIG. 2C are cross-sectional views illustrating examples of the light-emitting apparatus.

FIG. 3A is a top view illustrating an example of a light-emitting apparatus. FIG. 3B is a cross-sectional view illustrating the example of the light-emitting apparatus.

FIG. 4A to FIG. 4E are diagrams illustrating examples of electronic devices.

FIG. 5 is a cross-sectional view illustrating a light-emitting device in Example.

FIG. 6 is a graph showing emission spectra of light-emitting devices in Example 1.

FIG. 7 is a graph showing emission spectra of the light-emitting devices in Example 1.

FIG. 8 is a graph showing emission spectra of the light-emitting device and a mixed film in Example 1.

FIG. 9 is a graph showing emission spectra of the light-emitting device and the mixed film in Example 1.

FIG. 10 is a graph showing emission spectra of the light-emitting device and a mixed film in Example 1.

FIG. 11 is a graph showing emission spectra of the light-emitting device and the mixed film in Example 1.

FIG. 12 is a graph showing an absorption spectrum of [Ir(dmdpbq)₂(dpm)].

FIG. 13 is a graph showing an emission spectrum of [Ir(dmdpbq)₂(dpm)].

FIG. 14 is a graph showing a change in spectral radiance in accordance with radiance of the light-emitting device in Example 1.

FIG. 15 is a graph showing the relationship between radiance and CIE chromaticity coordinates (x, y) of the light-emitting device in Example 1.

FIG. 16 is a graph showing results of a reliability test of the light-emitting device in Example 1.

FIG. 17 is a graph showing emission spectra of light-emitting devices and a mixed film in Example 2.

FIG. 18 is a graph showing emission spectra of the light-emitting devices in Example 2.

FIG. 19 is a graph showing the relationship between guest material concentration and luminance/radiance of the light-emitting device according to Example 2.

FIG. 20 is a graph showing the relationship between guest material concentration and external quantum efficiency of the light-emitting device according to Example 2.

### MODE FOR CARRYING OUT THE INVENTION

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and a description thereof is not repeated. Furthermore, the same hatch pattern is used for the portions having similar functions, and the portions are not especially denoted by reference numerals in some cases.

In addition, the position, size, range, or the like of each structure shown in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be interchanged with each other depending on the case or circumstances. For example, the term “conductive layer” can be changed into the term “conductive film”. As another example, the term “insulating film” can be changed into the term “insulating layer”.

### Embodiment 1

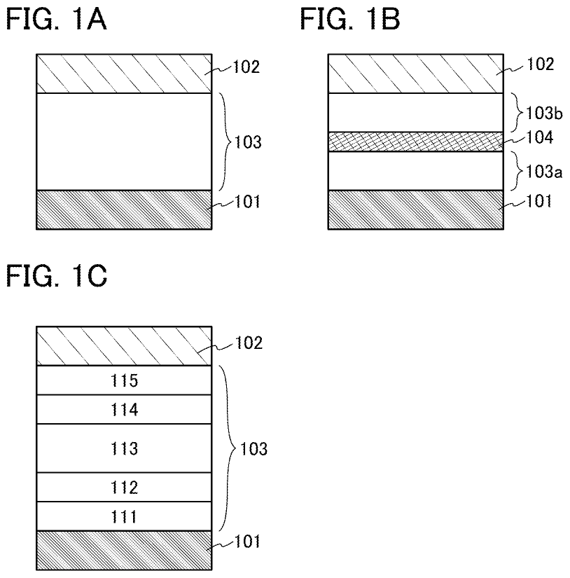

In this embodiment, a light-emitting device of one embodiment of the present invention will be described below with reference to FIG. 1.

The light-emitting device of one embodiment of the present invention includes a light-emitting organic compound (also referred to as a guest material) and a host material in a light-emitting layer.

The light-emitting device of one embodiment of the present invention has a function of emitting both near-infrared light and visible light.

Specifically, the light-emitting device of one embodiment of the present invention has a function of emitting near-infrared light originating from the guest material and visible light originating from the host material. Therefore, even when a light-emitting organic compound emitting visible light is not added, it is possible to achieve a light-emitting device having a function of emitting both near-infrared light and visible light.

In the light-emitting device of one embodiment of the present invention, the maximum peak wavelength (wavelength having the highest peak intensity) in an emission spectrum (electroluminescence (EL) spectrum) is greater than or equal to 750 nm and less than or equal to 900 nm, preferably greater than or equal to 780 nm and less than or equal to 880 nm.

The emission spectrum further has a peak in the visible light region. The peak wavelength in the visible light region is preferably greater than or equal to 450 nm and less than or equal to 650 nm.

In the case where visible light becomes noise in sensing with near-infrared light, for example, when the emission intensity of the visible light is enhanced in order that visible light emission can be easy to see, the accuracy of the sensing might decrease extremely. Thus, in order that the visible light emission can be easy to see even when the visible light has relatively low emission intensity, it is preferable to use light in a wavelength of a high luminosity factor as the visible light. When visible light emitted by the light-emitting device has a wavelength of a high luminosity factor, the emitted visible light becomes easy to see even when the emission intensity of the visible light is lower than the emission intensity of near-infrared light.

Specifically, the peak wavelength in the visible light region is further preferably higher than or equal to 450 nm and less than or equal to 550 nm. Accordingly, the luminosity factor of the visible light can be increased.

In the light-emitting device of one embodiment of the present invention, luminance A [cd/m²] and radiance B [W/sr/m²] preferably satisfy AB≥0.1 [cd·sr/W], further preferably satisfy AB>1 [cd·sr/W].

With luminance and radiance that satisfy the above formula, it is possible to achieve a light-emitting device that emits visible light easily seen and emits near-infrared light efficiently.

The light-emitting device of one embodiment of the present invention can emit near-infrared light efficiently. The use of such a light-emitting device makes it possible to achieve an electronic device that performs authentication, analysis, diagnosis, or the like with near-infrared light. The light-emitting device of one embodiment of the present invention can further emit visible light. Accordingly, the user can see visible light while authentication, analysis, diagnosis, or the like with near-infrared light is being carried out in the electronic device. Since the emission intensity of the visible light is sufficiently lower than the emission intensity of the near-infrared light, the visible light emitted by the light-emitting device can be inhibited from becoming noise in authentication, analysis, diagnosis, or the like performed with near-infrared light. Thus, the accuracy of authentication, analysis, diagnosis, or the like can be improved.

The difference between the HOMO level and the LUMO level of the host material is preferably greater than or equal to 1.90 eV and less than or equal to 2.75 eV, further preferably greater than or equal to 2.25 eV and less than or equal to 2.75 eV. Accordingly, the luminosity factor of the visible light emitted by the host material can be increased.

Note that the LUMO level and the HOMO level of the material can be derived from the electrochemical characteristics (the reduction potential and the oxidation potential) of the material that are measured by cyclic voltammetry (CV).

Here, in the case where the guest material is a substance emitting phosphorescence (phosphorescent material), an absorption band that is considered to contribute to light emission most greatly is an absorption wavelength corresponding to direct transition from a singlet ground state to a triplet excitation state and the vicinity thereof, i.e., an absorption band appearing on the longest wavelength side (lowest energy side). Therefore, it is considered preferable that emission spectra (a fluorescence spectrum and a phosphorescence spectrum) of the host material largely overlap with the longest-wavelength-side (lowest-energy-side) absorption band in the absorption spectrum of the phosphorescent material. Thus, transfer of excitation energy from the host material to the guest material is performed smoothly. Then, excitation energy of the host material is converted into excitation energy of the guest material, whereby the guest material emits light efficiently.

Accordingly, in order that the guest material can emit near-infrared light efficiently, it is preferable that light emitted by the host material have a long wavelength. However, light is extracted not only from the guest material but also from the host material in the light-emitting device of one embodiment of the present invention. At this time, when the emission wavelength of the host material is too long, the band gap becomes narrow, so that the emission quantum yield of the host material decreases. In addition, when the emission wavelength of the host material becomes longer than a wavelength range of a high luminosity factor, the luminosity factor of the light emitted by the host material is reduced.

Therefore, it is preferable that the maximum peak of the emission spectrum (photoluminescence (PL) spectrum) of the host material be on a higher energy side (shorter wavelength side) than a peak of a lowest-energy-side (longest-wavelength-side) absorption band in the absorption spectrum of the guest material and overlap with the absorption spectrum (or the absorption band). Thus, the luminosity factor of the light emitted by the host material can be increased and a decrease in the emission quantum yield of the host material can be inhibited. Accordingly, both near-infrared light and visible light can be extracted from the light-emitting device.

The energy of the maximum peak in the PL spectrum of the host material is preferably higher than the energy of a lowest-energy-side absorption edge in the absorption spectrum of the guest material. The energy of the maximum peak in the PL spectrum of the host material is preferably higher than the energy of the peak of the lowest-energy-side absorption band in the absorption spectrum of the guest material.

The energy of the maximum peak in the PL spectrum of the host material is preferably higher than the energy of the peak of the lowest-energy-side absorption band in the absorption spectrum of the guest material by 0.20 eV or more, further preferably by 0.30 eV or more, still further preferably by 0.40 eV or more.

The energy of the maximum peak in the PL spectrum of the host material is preferably higher than the energy of the lowest-energy-side absorption edge in the absorption spectrum of the guest material by 0.30 eV or more, further preferably by 0.40 eV or more, still further preferably by 0.50 eV or more.

When the emission spectrum of the light-emitting device of one embodiment of the present invention has a first peak (maximum peak) at greater than or equal to 750 nm and less than or equal to 900 nm and has a second peak at greater than or equal to 450 nm and less than or equal to 650 nm, the energy of the second peak is preferably higher than the energy of the peak of the lowest-energy-side absorption band in the absorption spectrum of the guest material by 0.35 eV or more, further preferably by 0.45 eV or more.

Here, in the case where a phosphorescent material is used as the guest material, the emission efficiency of the light-emitting device can be enhanced when the T₁ level (the energy level of the lowest triplet excited state) of the host material is higher than the T₁ level of the guest material. Meanwhile, the host material can convert singlet excitation energy into light emission. In order that visible light emission can be easily seen, it is preferable that the emission efficiency of visible light be high. When the host material emits visible light with a high luminosity factor and high emission efficiency, it is possible to transfer a large amount of excitation energy from the host material to the guest material, whereby a light-emitting device that emits visible light easily seen and emits near-infrared light efficiently can be obtained. To achieve this, a thermally activated delayed fluorescent (TADF) material is preferably used as the host material. When the TADF material, which has a small difference between the S₁ level (the energy level of the lowest singlet excited state) and the T₁ level, is used as the host material, the emission efficiency of the host material can be enhanced. For example, it is preferable that the difference between the singlet excitation energy level and the triplet excitation energy level of the host material be 0.2 eV or less.

Alternatively, a first organic compound and a second organic compound may be used as the host material to form an exciplex. The combination of the first organic compound and the second organic compound forms an exciplex. In this case, the host material can be regarded as a mixed material of the first organic compound and the second organic compound. With the use of the first organic compound and the second organic compound as the host material, an exciplex is formed when voltage is applied between a pair of electrodes in the light-emitting device.

An exciplex whose excited state is formed by two kinds of substances has an extremely small difference between the S₁ level and the T₁ level and functions as a TADF material that can convert triplet excitation energy into singlet excitation energy.

In the case where the host material includes the first organic compound and the second organic compound, light emission originating from an exciplex formed by the first organic compound and the second organic compound is observed from the light-emitting device of one embodiment of the present invention. Accordingly, in order that light emitted by the exciplex can be easily seen, the light emitted by the exciplex is preferably light with a high luminosity factor.

Here, the case where the heights of the energy levels are in the order of the HOMO level of the second organic compound<the HOMO level of the first organic compound<the LUMO level of the second organic compound<the LUMO level of the first organic compound is considered. In this case, in the exciplex formed by the two organic compounds, the LUMO level is derived from the second organic compound and the HOMO level is derived from the first organic compound.

Therefore, the difference between the HOMO level of the first organic compound and the LUMO level of the second organic compound is preferably greater than or equal to 1.90 eV and less than or equal to 2.75 eV, further preferably greater than or equal to 2.25 eV and less than or equal to 2.75 eV. Accordingly, the luminosity factor of visible light emitted by the exciplex can be increased.

An emission peak of the exciplex exists on a lower energy side (longer wavelength side) than an emission peak of the first organic compound and an emission peak of the second organic compound. Accordingly, it is relatively easy to overlap the PL spectrum of the exciplex with the longest-wavelength-side absorption band in the absorption spectrum of the guest material. Therefore, near-infrared light originating from the guest material can be emitted efficiently. Meanwhile, light emission is extracted not only from the guest material but also from the exciplex in the light-emitting device of one embodiment of the present invention.

Therefore, it is preferable that the maximum peak in the PL spectrum of the exciplex be on a higher energy side (shorter wavelength side) than the peak of the lowest-energy-side (longest-wavelength-side) absorption band in the absorption spectrum of the guest material and overlap with the absorption spectrum (or the absorption band). Accordingly, both near-infrared light and visible light can be extracted from the light-emitting device.

The energy of the maximum peak in the PL spectrum of the exciplex is preferably higher than the energy of the lowest-energy-side absorption edge in the absorption spectrum of the guest material. The energy of the maximum peak in the PL spectrum of the exciplex is preferably higher than the energy of the peak of the lowest-energy-side absorption band in the absorption spectrum of the guest material.

The energy of the maximum peak in the PL spectrum of the exciplex is preferably higher than the energy of the peak of the lowest-energy-side absorption band in the absorption spectrum of the guest material by 0.20 eV or more, further preferably by 0.30 eV or more, still further preferably by 0.40 eV or more.

The energy of the maximum peak in the PL spectrum of the exciplex is preferably higher than the energy of the lowest-energy-side absorption edge in the absorption spectrum of the guest material by 0.30 eV or more, further preferably by 0.40 eV or more, still further preferably by 0.50 eV or more.

In the light-emitting device of one embodiment of the present invention, the emission peak intensity of near-infrared light is preferably greater than or equal to 10 times and less than or equal to 10000 times the emission peak intensity of visible light. Since the light-emitting device of one embodiment of the present invention emits visible light having a wavelength of a high luminosity factor, it is possible to see the visible light sufficiently even when the emission intensity of the visible light is lower than the emission intensity of the near-infrared light.

The concentration of the guest material in the light-emitting layer is preferably greater than or equal to 0.1 wt % and less than or equal to 10 wt %, further preferably greater than or equal to 0.5 wt % and less than or equal to 5 wt %. As the concentration of the guest material becomes lower, luminance/radiance (a value obtained by dividing the value of luminance by the value of radiance) can be increased. In other words, as the concentration of the guest material becomes lower, the emission intensity of visible light becomes high with respect to the emission intensity of near-infrared light.

The guest material preferably has low emission intensity in the visible light region. Thus, in the light-emitting device of one embodiment of the present invention, a rising wavelength of the maximum peak on a short wavelength side in the emission spectrum is preferably greater than or equal to 650 nm.

A way of obtaining the rising wavelength in this specification and the like is described. First, a tangent at each point on a curve is drawn in order from a point on a short wavelength side in the emission spectrum in a linear scale, to a shortest-wavelength-side local maximum point of the local maximum points in the spectrum. The slope of the tangent becomes steep as the curve rises (the value of the vertical axis increases). A wavelength where the tangent drawn at a point at which the slope has a local maximum value on the shortest wavelength side intersects the origin is regarded as the rising wavelength. Note that a local maximum point at which the value of the vertical axis is less than or equal to 10% of that of the maximum peak is not included as the shortest-wavelength-side local maximum point.

The rising wavelength of the maximum peak on a short wavelength side in the PL spectrum of the guest material in a solution is preferably greater than or equal to 650 nm.

The external quantum efficiency of the light-emitting device of one embodiment of the present invention is preferably greater than or equal to 1%.

In particular, external quantum efficiency calculated from light emission originating from the guest material in the light-emitting device or external quantum efficiency calculated from near-infrared light emission in the light-emitting device is preferably greater than or equal to 1%.

To calculate the external quantum efficiency from the light emission originating from the guest material or the near-infrared light emission, the external quantum efficiency may be calculated with data on a certain wavelength range, for example. Specifically, the external quantum efficiency may be calculated from data on a wavelength range of greater than or equal to 600 nm and less than or equal to 1030 nm.

Since the emission intensity of the host material or the exciplex is sufficiently lower than the emission intensity of the guest material in the light-emitting device of one embodiment of the present invention, the external quantum efficiency can be regarded as the external quantum efficiency calculated from the light emission originating from the guest material in the light-emitting device or the external quantum efficiency calculated from the near-infrared light emission in the light-emitting device.

Alternatively, the external quantum efficiency may be calculated after waveform separation of the emission spectrum is performed to distinguish the light emission originating from the guest material from the light emission originating from the host material or the exciplex. In this case, the external quantum efficiency calculated from the light emission originating from the guest material in the light-emitting device of one embodiment of the present invention is preferably greater than or equal to 1%. Alternatively, the external quantum efficiency calculated from the near-infrared light emission in the light-emitting device of one embodiment of the present invention is preferably greater than or equal to 1%.

In the light-emitting device of one embodiment of the present invention, the emission color of visible light is sometimes changed when the intensity ratio between the light emission originating from the host material and the light emission originating from the exciplex is changed in accordance with the magnitude of radiance. Accordingly, the emission intensity of near-infrared light in the light-emitting device can be estimated from the emission color of visible light.

Specifically, CIE chromaticity coordinates (x1, y1) at first radiance and CIE chromaticity coordinates (x2, y2) at second radiance preferably satisfy one or both of x1>x2 and y1>y2, where the first radiance is lower than the second radiance.

The light-emitting organic compound preferably exhibits phosphorescence, in which case the emission efficiency of the light-emitting device can be increased. The light-emitting organic compound is particularly preferably an organometallic complex having a metal-carbon bond. In particular, the light-emitting organic compound is further preferably a cyclometalated complex. Furthermore, the light-emitting organic compound is preferably an orthometalated complex. These organic compounds are likely to exhibit phosphorescence, and thus can increase the emission efficiency of the light-emitting device. Consequently, the light-emitting device of one embodiment of the present invention preferably emits phosphorescence.

The organometallic complex having a metal-carbon bond is suitable for the light-emitting organic compound because of its higher emission efficiency and higher chemical stability than a porphyrin-based compound and the like.

In the case where the light-emitting organic compound is used as the guest material and another organic compound is used as the host material in the light-emitting layer, when a deep trough appears (a portion with low intensity appears) in the absorption spectrum of the light-emitting organic compound, excitation energy is not transferred smoothly from the host material to the guest material and the energy transfer efficiency is lowered, depending on the value of excitation energy of the host material. Here, in the absorption spectrum of the organometallic complex having a metal-carbon bond, many absorption bands, such as an absorption band derived from triplet MLCT (Metal to Ligand Charge Transfer) transition, an absorption band derived from singlet MLCT transition, and an absorption band derived from triplet π-π* transition, overlap each other; hence, a deep trough is less likely to appear in the absorption spectrum. Thus, the range of the value of excitation energy of the material that can be used as the host material can be widened, and the range of choices for the host material can be widened.

In addition, the light-emitting organic compound is preferably an iridium complex. For example, the light-emitting organic compound is preferably a cyclometalated complex using iridium as the central metal. Since the iridium complex has higher chemical stability than a platinum complex and the like, the use of the iridium complex as the light-emitting organic compound can increase the reliability of the light-emitting device. In terms of such stability, a cyclometalated complex of iridium is preferable, and an orthometalated complex of iridium is further preferable.

From the viewpoint of obtaining near-infrared light emission, the ligand of the above organometallic complex preferably has a structure in which a condensed heteroaromatic ring including 2 to 5 rings is coordinated to a metal. The condensed heteroaromatic ring preferably includes 3 or more rings. Moreover, the condensed heteroaromatic ring preferably includes 4 or less rings. As the number of rings included in the condensed heteroaromatic ring increases, the LUMO level can be lower and the wavelength of light emitted from the organometallic complex can be longer. Meanwhile, as the number of condensed heteroaromatic rings decreases, the sublimability can be increased. Consequently, by employing a condensed heteroaromatic ring including 2 to 5 rings, the LUMO level of the ligand is adequately lowered, and the wavelength of light that is emitted from the organometallic complex and derived from the (triplet) MLCT transition can be increased to the near-infrared wavelength while high sublimability is maintained. In addition, as the number of nitrogen atoms (N) included in the condensed heteroaromatic ring increases, the LUMO level can be lower. Therefore, the number of nitrogen atoms (N) included in the condensed heteroaromatic ring is preferably two or more, particularly preferably two.

The light-emitting device of one embodiment of the present invention can be formed into a film shape and is easily increased in area, and thus can be used as a planar light source that emits near-infrared light.

### [Structure Example of Light-Emitting Device]

### <<Basic Structure of Light-Emitting Device>>

FIG. 1A to FIG. 1C illustrate examples of a light-emitting device including an EL layer between a pair of electrodes.

The light-emitting device illustrated in FIG. 1A has a structure in which an EL layer 103 is provided between a first electrode 101 and a second electrode 102 (a single structure). The EL layer 103 includes at least a light-emitting layer.

The light-emitting device may include a plurality of EL layers between a pair of electrodes. FIG. 1B illustrates a light-emitting device having a tandem structure in which two EL layers (an EL layer 103a and an EL layer 103b) are provided between a pair of electrodes and a charge-generation layer 104 is provided between the two EL layers. The light-emitting device having a tandem structure can be driven at low voltage and have low power consumption.

The charge-generation layer 104 has a function of injecting electrons into one of the EL layer 103a and the EL layer 103b and injecting holes into the other of the EL layers when voltage is applied to the first electrode 101 and the second electrode 102. Thus, in FIG. 1B, when voltage is applied such that the potential of the first electrode 101 is higher than that of the second electrode 102, the charge-generation layer 104 injects electrons into the EL layer 103a and injects holes into the EL layer 103b.

Note that in terms of light extraction efficiency, the charge-generation layer 104 preferably transmits visible light and near-infrared light (specifically, each of the transmittance of visible light and the transmittance of near-infrared light of the charge-generation layer 104 is preferably greater than or equal to 40%). The charge-generation layer 104 functions even when having lower conductivity than the first electrode 101 and the second electrode 102.

FIG. 1C illustrates an example of a stacked-layer structure of the EL layer 103. In this embodiment, the case where the first electrode 101 functions as an anode and the second electrode 102 functions as a cathode is described as an example. The EL layer 103 has a structure in which a hole-injection layer 111, a hole-transport layer 112, a light-emitting layer 113, an electron-transport layer 114, and an electron-injection layer 115 are stacked in this order over the first electrode 101. Each of the hole-injection layer 111, the hole-transport layer 112, the light-emitting layer 113, the electron-transport layer 114, and the electron-injection layer 115 may have a single-layer structure or a stacked-layer structure. Note that in the case where a plurality of EL layers are provided as in the tandem structure illustrated in FIG. 1B, each of the EL layers can have a stacked-layer structure similar to that of the EL layer 103 illustrated in FIG. 1C. When the first electrode 101 serves as a cathode and the second electrode 102 serves as an anode, the stacking order is reversed.

The light-emitting layer 113 contains a light-emitting substance and a plurality of substances in appropriate combination, whereby fluorescence or phosphorescence with a desired wavelength can be obtained. The EL layer 103a and the EL layer 103b illustrated in FIG. 1B may exhibit different wavelengths.

The light-emitting device of one embodiment of the present invention may have a structure in which light obtained from the EL layer is resonated between the pair of electrodes in order to intensify the light. For example, when the first electrode 101 is a reflective electrode (an electrode having a property of reflecting visible light and near-infrared light) and the second electrode 102 is a transflective electrode (an electrode having properties of transmitting and reflecting visible light and near-infrared light) in FIG. 1C to form a micro optical resonator (microcavity) structure, light emission obtained from the EL layer 103 can be intensified.

Note that in the case where the first electrode 101 of the light-emitting device is a reflective electrode having a stacked-layer structure of a conductive film having a property of reflecting near-infrared light and a conductive film having a property of transmitting near-infrared light, optical adjustment can be performed by controlling the thicknesses of the conductive film having the transmitting property. Specifically, when the wavelength of light obtained from the light-emitting layer 113 is λ, the distance between the first electrode 101 and the second electrode 102 is preferably adjusted to be in the neighborhood of mλ/2 (m is a natural number).

To amplify desired light (wavelength: λ) obtained from the light-emitting layer 113, the optical path length from the first electrode 101 to a region where the desired light is obtained in the light-emitting layer 113 (a light-emitting region) and the optical path length from the second electrode 102 to the region where the desired light is obtained in the light-emitting layer 113 (a light-emitting region) are preferably adjusted to be in the neighborhood of (2m′+1)λ/4 (m′ is a natural number). Here, the light-emitting region refers to a region where holes and electrons are recombined in the light-emitting layer 113.

By performing such optical adjustment, the spectrum of light obtained from the light-emitting layer 113 can be narrowed, and light with a desired wavelength can be obtained.

Note that in the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained wherever the reflective regions may be set in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer from which the desired light is obtained; thus, it is assumed that the above effect can be sufficiently obtained with a given position in the first electrode 101 being supposed to be the reflective region and a given position in the light-emitting layer from which the desired light is obtained being supposed to be the light-emitting region.

At least one of the first electrode 101 and the second electrode 102 has a property of transmitting visible light and near-infrared light. The transmittance of visible light and the transmittance of near-infrared light of the electrode having a property of transmitting visible light and near-infrared light are each greater than or equal to 40%. In the case where the electrode having a property of transmitting visible light and near-infrared light is the above-described transflective electrode, the reflectance of visible light and the reflectance of near-infrared of the electrode are each greater than or equal to 20%, preferably greater than or equal to 40% and less than 100%, preferably less than or equal to 95%, and may be less than or equal to 80% or less than or equal to 70%. For example, the reflectance of near-infrared light of the electrode is greater than or equal to 20% and less than or equal to 80%, preferably greater than or equal to 40% and less than or equal to 70%. The electrode preferably has a resistivity less than or equal to 1×10⁻² Ωcm.

In the case where the first electrode 101 or the second electrode 102 is a reflective electrode, the reflectance of visible light and the reflectance of near-infrared light of the reflective electrode are each greater than or equal to 40% and less than or equal to 100%, preferably greater than or equal to 70% and less than or equal to 100%. The electrode preferably has a resistivity less than or equal to 1×10⁻² Ψcm.

### <<Specific Structure and Fabrication Method of Light-Emitting Device>>

Next, a specific structure and a fabrication method of the light-emitting device will be described. Here, the light-emitting device having the single structure illustrated in FIG. 1C is used for the description.

### <First Electrode and Second Electrode>

As materials for forming the first electrode 101 and the second electrode 102, any of the following materials can be used in an appropriate combination as long as the functions of the electrodes described above can be fulfilled. For example, a metal, an alloy, an electrically conductive compound, a mixture of these, and the like can be used as appropriate. Specific examples include In—Sn oxide (also referred to as ITO), In—Si—Sn oxide (also referred to as ITSO), In—Zn oxide, and In—W—Zn oxide. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) and an alloy containing an appropriate combination of any of these metals. It is also possible to use an element belonging to Group 1 or Group 2 in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these, graphene, and the like.

Note that when a light-emitting device having a microcavity structure is formed, the first electrode 101 is formed as a reflective electrode and the second electrode 102 is formed as a transflective electrode. Thus, a single layer or stacked layers can be formed using one or more desired conductive materials. Note that the second electrode 102 is formed after formation of the EL layer 103, with the use of a material selected as described above. For fabrication of these electrodes, a sputtering method or a vacuum evaporation method can be used.

When the first electrode 101 is an anode in the light-emitting device illustrated in FIG. 1C, the hole-injection layer 111 and the hole-transport layer 112 are sequentially stacked over the first electrode 101 by a vacuum evaporation method.

### <Hole-Injection Layer and Hole-Transport Layer>

The hole-injection layer 111 is a layer injecting holes from the first electrode 101 serving as the anode to the EL layer 103, and is a layer including a material with a high hole-injection property.

As the material having a high hole-injection property, a transition metal oxide such as molybdenum oxide, vanadium oxide, ruthenium oxide, tungsten oxide, or manganese oxide or a phthalocyanine-based compound such as phthalocyanine (abbreviation: H₂Pc) or copper phthalocyanine (abbreviation: CuPc) can be used, for example.

As the material having a high hole-injection property, it is possible to use, for example, an aromatic amine compound such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), or 3-[N-(1-naphthyl)-N-(9-phenylcarbazol-3-yl)amino]-9-phenylcarbazole (abbreviation: PCzPCN1).

As the material having a high hole-injection property, it is possible to use, for example, poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), or poly[N,N-bis(4-butylphenyl)-N,N-bis(phenyl)benzidine](abbreviation: Poly-TPD). Alternatively, it is also possible to use, for example, a high molecular compound to which acid is added, such as poly(3,4-ethylenedioxythiophene)/poly(styrenesulfonic acid) (abbreviation: PEDOT/PSS) or polyaniline/poly(styrenesulfonic acid) (PAni/PSS).

As the material having a high hole-injection property, a composite material containing a hole-transport material and an acceptor material (an electron-accepting material) can also be used. In this case, the acceptor material extracts electrons from the hole-transport material, so that holes are generated in the hole-injection layer 111 and the holes are injected into the light-emitting layer 113 through the hole-transport layer 112. Note that the hole-injection layer 111 may be formed using a single layer of a composite material containing a hole-transport material and an acceptor material, or may be formed using a stack including a layer of a hole-transport material and a layer of an acceptor material.

The hole-transport layer 112 is a layer transporting holes, which are injected from the first electrode 101 by the hole-injection layer 111, to the light-emitting layer 113. A hole-transport layer 112 is a layer containing a hole-transport material. It is particularly preferable that the HOMO level of the hole-transport material used in the hole-transport layer 112 be the same as or close to the HOMO level of the hole-injection layer 111.

As the acceptor material used for the hole-injection layer 111, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. Alternatively, organic acceptors such as a quinodimethane derivative, a chloranil derivative, and a hexaazatriphenylene derivative can be used. Examples of materials having an electron-withdrawing group (halogen group or cyano group) include 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), and 1,3,4,5,7,8-hexafluorotetracyano-naphthoquinodimethane (abbreviation: F6-TCNNQ). A compound in which electron-withdrawing groups are bonded to a condensed aromatic ring having a plurality of heteroatoms, such as HAT-CN, is particularly preferable because it is thermally stable. A [3]radialene derivative including an electron-withdrawing group (in particular, a cyano group or a halogen group such as a fluoro group) has a very high electron-accepting property and thus is preferable; specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

The hole-transport materials used for the hole-injection layer 111 and the hole-transport layer 112 are preferably substances with a hole mobility greater than or equal to 10⁻⁶ cm²/Vs. Note that other substances can also be used as long as they have a property of transporting more holes than electrons.

As the hole-transport material, materials having a high hole-transport property, such as a π-electron-rich heteroaromatic compound (e.g., a carbazole derivative, a thiophene derivative, and a furan derivative) and an aromatic amine (a compound having an aromatic amine skeleton), are preferable.

Examples of the carbazole derivative (a compound having a carbazole skeleton) include a bicarbazole derivative (e.g., a 3,3′-bicarbazole derivative) and aromatic amine having a carbazolyl group.

Specific examples of the bicarbazole derivative (e.g., a 3,3′-bicarbazole derivative) include 3,3′-bis(9-phenyl-9H-carbazole) (abbreviation: PCCP), 9,9′-bis(1,1′-biphenyl-4-yl)-3,3′-bi-9H-carbazole, 9,9′-bis(1,1′-biphenyl-3-yl)-3,3′-bi-9H-carbazole, 9-(1,1′-biphenyl-3-yl)-9′-(1,1′-biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: βNCCP).

Specific examples of the aromatic amine having a carbazolyl group include 4-phenyl-4′-(9-phenyl-9H-carbazol-3-yl)triphenylamine (abbreviation: PCBA1BP), N-(4-biphenyl)-N-(9,9-dimethyl-9H-fluoren-2-yl)-9-phenyl-9H-carbazol-3-amine (abbreviation: PCBiF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N-bis(9-phenylcarbazol-3-yl)-N,N-diphenylbenzene-1,3-diamine (abbreviation: PCA2B), N,N,N′-triphenyl-N,N,N′-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]spiro-9,9′-bifluoren-2-amine (abbreviation: PCBASF), PCzPCA1, PCzPCA2, PCzPCN1, 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino]spiro-9,9′-bifluorene (abbreviation: PCASF), N-[4-(9H-carbazol-9-yl)phenyl]-N-(4-phenyl)phenylaniline (abbreviation: YGA1BP), N,N-bis[4-(carbazol-9-yl)phenyl]-N,N-diphenyl-9,9-dimethylfluorene-2,7-diamine (abbreviation: YGA2F), and 4,4′,4″-tris(carbazol-9-yl)triphenylamine (abbreviation: TCTA).

In addition to the above, other examples of the carbazole derivative include 3-[4-(9-phenanthryl)-phenyl]-9-phenyl-9H-carbazole (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA).

Specific examples of the thiophene derivative (a compound having a thiophene skeleton) and the furan derivative (a compound having a furan skeleton) include compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV), 4,4′,4″-(benzene-1,3,5-triyl)tri(dibenzofuran) (abbreviation: DBF3P-II), and 4-{3-[3-(9-phenyl-9H-fluoren-9-yl)phenyl]phenyl}dibenzofuran (abbreviation: mmDBFFLBi-II).

Specific examples of the aromatic amine include 4,4′-bis[N-(1-naphthyl)-N-phenylamino]biphenyl (abbreviation: NPB or α-NPD), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 2,7-bis[N-(4-diphenylaminophenyl)-N-phenylamino]spiro-9,9′-bifluorene (abbreviation: DPA2SF), 4,4′,4″-tris[N-(1-naphthyl)-N-phenylamino]triphenylamine (abbreviation: 1′-TNATA), TDATA, m-MTDATA, N,N′-di(p-tolyl)-N,N′-diphenyl-p-phenylenediamine (abbreviation: DTDPPA), DPAB, DNTPD, and DPA3B.

As the hole-transport material, a high molecular compound such as PVK, PVTPA, PTPDMA, or Poly-TPD can also be used.

The hole-transport material is not limited to the above examples, and one of or a combination of various known materials can be used as the hole-transport material in the hole-injection layer 111 and the hole-transport layer 112.

In the light-emitting device illustrated in FIG. 1C, the light-emitting layer 113 is formed over the hole-transport layer 112 by a vacuum evaporation method.

### <Light-Emitting Layer>

The light-emitting layer 113 is a layer containing a light-emitting substance.

The light-emitting device of one embodiment of the present invention contains a light-emitting organic compound as the light-emitting substance. The light-emitting organic compound emits near-infrared light. Specifically, the maximum peak wavelength of light emitted by the light-emitting organic compound is greater than 750 nm and less than or equal to 900 nm.

As the light-emitting organic compound, an organometallic complex that will be described as a guest material (phosphorescent material) in a later example, bis{4,6-dimethyl-2-[3-(3,5-dimethylphenyl)-2-benzo[g]quinoxalinyl-κN]phenyl-κC}(2,2,6,6-tetramethyl-3,5-heptanedionato-κ²O,O′)iridium(III) (abbreviation: [Ir(dmdpbq)₂(dpm)]), can be used, for example.

Alternatively, as the light-emitting organic compound, tetraphenyltetrabenzo porphyrin platinum(II) can be used, for example.

The light-emitting layer 113 can include one or more kinds of light-emitting substances.

The light-emitting layer 113 includes one or more kinds of organic compounds (a host material) in addition to a light-emitting substance (a guest material). As the one or more kinds of organic compounds, one or both of the hole-transport material and the electron-transport material described in this embodiment can be used. As the one or more kinds of organic compounds, a bipolar material may be used.

There is no particular limitation on the light-emitting substance that can be used for the light-emitting layer 113, and it is possible to use a light-emitting substance that converts singlet excitation energy into light in the near-infrared light range or a light-emitting substance that converts triplet excitation energy into light in the near-infrared light range.

As an example of the light-emitting substance that converts singlet excitation energy into light, a substance that exhibits fluorescence (a fluorescent material) can be given; examples include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the light-emitting substance converting triplet excitation energy into light include a substance emitting phosphorescence (phosphorescent material) and a TADF material exhibiting thermally activated delayed fluorescence.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

As the host material used in the light-emitting layer 113, one or more kinds of substances having a larger energy gap than the light-emitting substance can be used.

In the case where the light-emitting substance used in the light-emitting layer 113 is a fluorescent material, an organic compound used in combination with the light-emitting substance is preferably an organic compound that has a high energy level in a singlet excited state and has a low energy level in a triplet excited state.

In the case where the light-emitting substance is a fluorescent material, examples of the organic compound that can be used in combination with the light-emitting substance include fused polycyclic aromatic compounds, such as an anthracene derivative, a tetracene derivative, a phenanthrene derivative, a pyrene derivative, a chrysene derivative, and a dibenzo[g,p]chrysene derivative.

Specific examples of the organic compound (the host material) used in combination with the fluorescent material include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), PCPN, 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), 4-(9H-carbazol-9-yl)-4′-(10-phenyl-9-anthryl)triphenylamine (abbreviation: YGAPA), N,9-diphenyl-N-[4-(10-phenyl-9-anthryl)phenyl]-9H-carbazol-3-amine (abbreviation: PCAPA), N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetraamine (abbreviation: DBC1), CzPA, 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)-biphenyl-4′-yl}anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,93-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, and 5,12-bis(biphenyl-2-yl)tetracene.

In the case where the light-emitting substance is a phosphorescent material, as the organic compound used in combination with the light-emitting substance, an organic compound that has higher triplet excitation energy (energy difference between a ground state and a triplet excited state) than the light-emitting substance is selected.

In the case where a plurality of organic compounds (e.g., a first host material and a second host material) are used in combination with the light-emitting substance in order to form an exciplex, the plurality of organic compounds are preferably mixed with a phosphorescent material (particularly an organometallic complex).

Such a structure makes it possible to efficiently obtain light emission utilizing ExTET (Exciplex-Triplet Energy Transfer), which is energy transfer from an exciplex to a light-emitting substance. Note that a combination of a plurality of organic compounds that easily forms an exciplex is preferable, and it is particularly preferable to combine a compound that easily accepts holes (a hole-transport material) and a compound that easily accepts electrons (an electron-transport material). As the hole-transport material and the electron-transport material, specifically, any of the materials described in this embodiment can be used. With the above structure, high efficiency, low voltage, and a long lifetime of the light-emitting device can be achieved at the same time.

In the case where the light-emitting substance is a phosphorescent material, examples of the organic compounds that can be used in combination with the light-emitting substance include an aromatic amine, a carbazole derivative, a dibenzothiophene derivative, a dibenzofuran derivative, a zinc- or aluminum-based metal complex, an oxadiazole derivative, a triazole derivative, a benzimidazole derivative, a quinoxaline derivative, a dibenzoquinoxaline derivative, a pyrimidine derivative, a triazine derivative, a pyridine derivative, a bipyridine derivative, and a phenanthroline derivative.

Among the above-described compounds, specific examples of the aromatic amine, (a compound having an aromatic amine skeleton), the carbazole derivative, the dibenzothiophene derivative (thiophene derivative), and the dibenzofuran derivative (furan derivative), which are organic compounds having a high hole-transport property, are the same as the compounds given above as specific examples of the hole-transport material.

Specific examples of the zinc- and aluminum-based metal complexes, which are organic compounds having a high electron-transport property, include metal complexes including a quinoline skeleton or a benzoquinoline skeleton, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), and bis(8-quinolinolato)zinc(II) (abbreviation: Znq).

A metal complex having an oxazole-based or thiazole-based ligand, such as bis[2-(2-benzoxazolyl)phenolato]zinc(II) (abbreviation: ZnPBO) or bis[2-(2-benzothiazolyl)phenolato]zinc(II) (abbreviation: ZnBTZ), or the like can also be used.

Specific examples of the oxadiazole derivative, the triazole derivative, the benzimidazole derivative, the benzimidazole derivative, the quinoxaline derivative, the dibenzoquinoxaline derivative, and the phenanthroline derivative, which are organic compounds having a high electron-transport property, include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), 4,4′-bis(5-methylbenzoxazol-2-yl)stilbene (abbreviation: BzOs, bathophenanthroline (abbreviation: Bphen), bathocuproine (abbreviation: BCP), 2,9-bis(naphthalen-2-yl)-4,7-diphenyl-1,10-phenanthroline (abbreviation: NBphen), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), and 6-[3-(dibenzothiophen-4-yl)phenyl]dibenzo[f,h]quinoxaline (abbreviation: 6mDBTPDBq-II).

Specific examples of a heterocyclic compound having a diazine skeleton, a heterocyclic compound having a triazine skeleton, and a heterocyclic compound having a pyridine skeleton, which are organic compounds having a high electron-transport property, include 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluorene-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 3,5-bis(3-(9H-carbazol-9-yl)phenyl)pyridine (abbreviation: 35DCzPPy), and 1,3,5-tri[3-(3-pyridyl)phenyl]benzene (abbreviation: TmPyPB).

As the organic compound having a high electron-transport property, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can also be used.

The TADF material is a material that has a small difference between the S₁ level and the T₁ level and has a function of converting triplet excitation energy into singlet excitation energy by reverse intersystem crossing. Thus, it is possible to upconvert triplet excitation energy into singlet excitation energy (reverse intersystem crossing) using a little thermal energy and to efficiently generate a singlet excited state. In addition, the triplet excitation energy can be converted into light emission. Thermally activated delayed fluorescence is efficiently obtained under the condition where the difference in energy between the S₁ level and the T₁ level is greater than or equal to 0 eV and less than or equal to 0.2 eV, preferably greater than or equal to 0 eV and less than or equal to 0.1 eV. Delayed fluorescence by the TADF material refers to light emission having a spectrum similar to that of normal fluorescence and an extremely long lifetime. The lifetime is 10⁻⁶ seconds or longer, preferably 10⁻³ seconds or longer.

A phosphorescent spectrum observed at low temperatures (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably less than or equal to 0.3 eV, further preferably less than or equal to 0.2 eV.

The TADF material may be used as a guest material or may be used as a host material.

Examples of the TADF material include fullerene, a derivative thereof, an acridine derivative such as proflavine, and eosin. Other examples include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

Alternatively, it is possible to use a heterocyclic compound having a π-electron rich heteroaromatic ring and a π-electron deficient heteroaromatic ring, such as 2-(biphenyl-4-yl)-4,6-bis(12-phenylindolo[2,3-a]carbazol-11-yl)-1,3,5-triazine (abbreviation: PIC-TRZ), PCCzPTzn, 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Note that a substance in which a π-electron rich heteroaromatic ring is directly bonded to a π-electron deficient heteroaromatic ring is particularly preferable because both the donor property of the π-electron rich heteroaromatic ring and the acceptor property of the π-electron deficient heteroaromatic ring are improved and the energy difference between the singlet excited state and the triplet excited state becomes small.

Note that the TADF material can also be used in combination with another organic compound. In particular, the TADF material can be used in combination with the host material, the hole-transport material, and the electron-transport material described above.

Furthermore, when used in combination with a low molecular material or a high molecular material, the above materials can be used to form the light-emitting layer 113. For the deposition, a known method (an evaporation method, a coating method, a printing method, or the like) can be used as appropriate.

In the light-emitting device illustrated in FIG. 1C, the electron-transport layer 114 is formed over the light-emitting layer 113.

### <Electron-Transport Layer>

The electron-transport layer 114 is a layer that transports electrons, which are injected from the second electrode 102 by the electron-injection layer 115, to the light-emitting layer 113. Note that the electron-transport layer 114 is a layer containing an electron-transport material. The electron-transport material used in the electron-transport layer 114 is preferably a substance having an electron mobility higher than or equal to 1×10⁻⁶ cm²/Vs. Note that other substances can also be used as long as they have a property of transporting more electrons than holes.

As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

As specific examples of the electron-transport material, the above-described materials can be used.

Next, in the light-emitting device illustrated in FIG. 1C, the electron-injection layer 115 is formed over the electron-transport layer 114 by a vacuum evaporation method.

### <Electron-Injection Layer>

The electron-injection layer 115 is a layer that contains a substance having a high electron-injection property. For the electron-injection layer 115, an alkali metal, an alkaline earth metal, or a compound thereof such as lithium fluoride (LiF), cesium fluoride (CsF), calcium fluoride (CaF₂), or lithium oxide (LiOₓ) can be used. A rare earth metal compound such as erbium fluoride (ErF₃) can also be used. In addition, an electride may be used for the electron-injection layer 115. Examples of the electride include a substance in which electrons are added at high concentration to calcium oxide-aluminum oxide. Any of the above-described substances for forming the electron-transport layer 114 can also be used.

For the electron-injection layer 115, a composite material containing an electron-transport material and a donor material (an electron-donating material) may be used. Such a composite material is excellent in an electron-injection property and an electron-transport property because electrons are generated in the organic compound by the electron donor. The organic compound here is preferably a material excellent in transporting the generated electrons; specifically, for example, the above-described electron-transport materials used in the electron-transport layer 114 (e.g., a metal complex or a heteroaromatic compound) can be used. As the electron donor, a substance exhibiting a property of donating electrons to an organic compound is used. Specifically, an alkali metal, an alkaline earth metal, and a rare earth metal are preferable, and lithium, cesium, magnesium, calcium, erbium, ytterbium, and the like are given. In addition, an alkali metal oxide and an alkaline earth metal oxide are preferable, and lithium oxide, calcium oxide, barium oxide, and the like are given. Alternatively, a Lewis base such as magnesium oxide can be used. Further alternatively, an organic compound such as tetrathiafulvalene (abbreviation: TTF) can be used.

### <Charge-Generation Layer>

In the light-emitting device illustrated in FIG. 1B, the charge-generation layer 104 has a function of injecting electrons into the EL layer 103a and injecting holes into the EL layer 103b when voltage is applied between the first electrode 101 (the anode) and the second electrode 102 (the cathode).

The charge-generation layer 104 may contain a hole-transport material and an acceptor material (an electron-accepting material) or may contain an electron-transport material and a donor material. Forming the charge-generation layer 104 with such a structure can inhibit an increase in the driving voltage that would be caused by stacking EL layers.

As the hole-transport material, the acceptor material, the electron-transport material, and the donor material, the above-described materials can be used.

For fabrication of the light-emitting device in this embodiment, a vacuum process such as an evaporation method or a solution process such as a spin coating method or an ink-jet method can be used. In the case of using an evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the functional layers (the hole-injection layer, the hole-transport layer, the light-emitting layer, the electron-transport layer, and the electron-injection layer) included in the EL layer and the charge-generation layer can be formed by an evaporation method (a vacuum evaporation method or the like), a coating method (a dip coating method, a die coating method, a bar coating method, a spin coating method, a spray coating method, or the like), a printing method (an ink-jet method, a screen printing (stencil) method, an offset printing (planography) method, a flexography (relief printing) method, a gravure printing method, a micro-contact printing method, or the like), or the like.

Materials of the functional layers included in the EL layer 103 and the charge-generation layer are not limited to the above-described corresponding materials. For example, as the materials of the functional layers, a high molecular compound (e.g., an oligomer, a dendrimer, and a polymer), a middle molecular compound (a compound between a low molecular compound and a high molecular compound with a molecular weight of 400 to 4000), or an inorganic compound (e.g., a quantum dot material) may be used. As the quantum dot material, a colloidal quantum dot material, an alloyed quantum dot material, a core-shell quantum dot material, a core quantum dot material, or the like can be used.

In the light-emitting device of one embodiment of the present invention, light emitted by the host material or light emitted by the exciplex formed by the host materials is easily seen. The light is in a wavelength range with high visibility; thus, even when the emission intensity of the light is lower than that of the near-infrared light emitted by the guest material, it is possible to see the light sufficiently. Accordingly, a light-emitting device that emits visible light easily seen and emits near-infrared light efficiently can be achieved.

In the light-emitting device of one embodiment of the present invention, the luminance A [cd/m²] and the radiance B [W/sr/m²] satisfy A/B≥0.1 [cd·sr/W]. Therefore, a light-emitting device that emits visible light easily seen and emits near-infrared light efficiently can be achieved.

This embodiment can be combined with the other embodiments as appropriate. In this specification, in the case where a plurality of structure examples are shown in one embodiment, the structure examples can be combined as appropriate.

### Embodiment 2

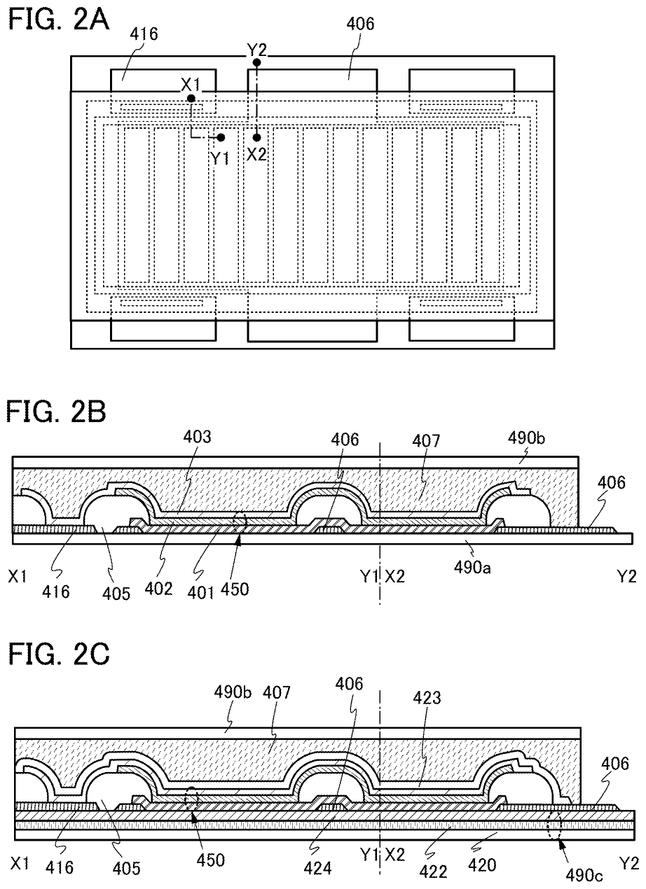

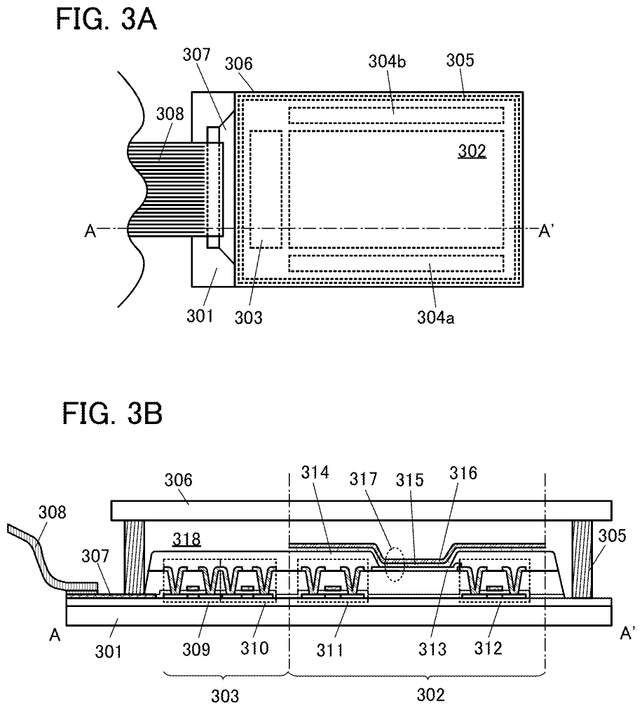

In this embodiment, a light-emitting apparatus of one embodiment of the present invention will be described with reference to FIG. 2 and FIG. 3.

The light-emitting apparatus of this embodiment includes the light-emitting device described in Embodiment 1. Therefore, a light-emitting apparatus that emits both near-infrared light and visible light can be achieved.

### [Structure Example 1 of Light-Emitting Apparatus]

FIG. 2A is a top view of a light-emitting apparatus, and FIG. 2B and FIG. 2C are cross-sectional views along dashed-dotted lines X1-Y1 and X2-Y2 in FIG. 2A. The light-emitting apparatus illustrated in FIG. 2A to FIG. 2C can be used as a lighting device, for example. The light-emitting apparatus can have a bottom-emission, top-emission, or dual-emission structure.

The light-emitting apparatus illustrated in FIG. 2B includes a substrate 490a, a substrate 490b, a conductive layer 406, a conductive layer 416, an insulating layer 405, an organic EL device 450 (a first electrode 401, an EL layer 402, and a second electrode 403), and an adhesive layer 407. As the organic EL device 450, the light-emitting device described in Embodiment 1 can be used.

The organic EL device 450 includes the first electrode 401 over the substrate 490a, the EL layer 402 over the first electrode 401, and the second electrode 403 over the EL layer 402. The organic EL device 450 is sealed by the substrate 490a, the adhesive layer 407, and the substrate 490b.

End portions of the first electrode 401, the conductive layer 406, and the conductive layer 416 are covered with the insulating layer 405. The conductive layer 406 is electrically connected to the first electrode 401, and the conductive layer 416 is electrically connected to the second electrode 403. The conductive layer 406 covered with the insulating layer 405 with the first electrode 401 positioned therebetween functions as an auxiliary wiring and is electrically connected to the first electrode 401. It is preferable that the auxiliary wiring electrically connected to the electrode of the organic EL device 450 be provided, in which case a voltage drop due to the resistance of the electrode can be inhibited. The conductive layer 406 may be provided over the first electrode 401. An auxiliary wiring that is electrically connected to the second electrode 403 may be provided, for example, over the insulating layer 405.

For each of the substrate 490a and the substrate 490b, glass, quartz, ceramic, sapphire, an organic resin, or the like can be used. When a flexible material is used for the substrate 490a and the substrate 490b, the flexibility of a display device can be increased.

A light-emitting surface of the light-emitting apparatus may be provided with a light extraction structure for increasing the light extraction efficiency, an antistatic film inhibiting the attachment of a foreign substance, a water repellent film suppressing the attachment of stain, a hard coat film suppressing generation of a scratch in use, an impact absorption layer, or the like.

Examples of an insulating material that can be used for the insulating layer 405 include a resin such as an acrylic resin and an epoxy resin, and an inorganic insulating material such as silicon oxide, silicon oxynitride, silicon nitride oxide, silicon nitride, and aluminum oxide.

For the adhesive layer 407, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-component resin may be used. Alternatively, an adhesive sheet or the like may be used.

The light-emitting apparatus illustrated in FIG. 2C includes a barrier layer 490c, the conductive layer 406, the conductive layer 416, the insulating layer 405, the organic EL device 450, the adhesive layer 407, a barrier layer 423, and the substrate 490b.

The barrier layer 490c illustrated in FIG. 2C includes a substrate 420, an adhesive layer 422, and an insulating layer 424 having a high barrier property.

In the light-emitting apparatus illustrated in FIG. 2C, the organic EL device 450 is provided between the insulating layer 424 having a high barrier property and the barrier layer 423. Thus, even when resin films with relatively low water resistance or the like are used as the substrate 420 and the substrate 490b, a reduction in lifetime due to entry of impurities such as water into the organic EL device can be inhibited.

For each of the substrate 420 and the substrate 490b, for example, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for the substrate 420 and the substrate 490b.

An inorganic insulating film is preferably used as the insulating layer 424 having a high barrier property. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

The barrier layer 423 preferably includes at least a single-layer inorganic film. For example, the barrier layer 423 can have a single-layer structure of an inorganic film or a stacked-layer structure of an inorganic film and an organic film. As the inorganic film, the above-described inorganic insulating film is preferable. An example of the stacked-layer structure is a structure in which a silicon oxynitride film, a silicon oxide film, an organic film, a silicon oxide film, and a silicon nitride film are formed in this order. When the barrier layer has a stacked-layer structure of an inorganic film and an organic film, entry of impurities that can enter the organic EL device 450 (typically, hydrogen, water, and the like) can be suitably inhibited.

The insulating layer 424 having a high barrier property and the organic EL device 450 can be directly formed on the substrate 420 having flexibility. In that case, the adhesive layer 422 is not necessary. Alternatively, the insulating layer 424 and the organic EL device 450 can be formed over a rigid substrate with a separation layer provided therebetween and then transferred to the substrate 420. For example, the insulating layer 424 and the organic EL device 450 may be transferred to the substrate 420 in the following manner: the insulating layer 424 and the organic EL device 450 are separated from the rigid substrate by application of heat, force, laser light, or the like to the separation layer, and then the insulating layer 424 and the organic EL device 450 are bonded to the substrate 420 with the use of the adhesive layer 422. For the separation layer, a stacked-layer structure of inorganic films including a tungsten film and a silicon oxide film, or an organic resin film of polyimide or the like can be used, for example. In the case where a rigid substrate is used, the insulating layer 424 can be formed at high temperature as compared to the case where a resin substrate or the like is used; thus, the insulating layer 424 can have high density and an excellent barrier property.

### [Structure Example 2 of Light-Emitting Apparatus]

The light-emitting apparatus of one embodiment of the present invention can be of passive matrix type or active matrix type. An active-matrix light-emitting apparatus will be described with reference to FIG. 3.

FIG. 3A is atop view of the light-emitting apparatus. FIG. 3B is a cross-sectional view along dashed-dotted line A-A′ in FIG. 3A.

The active-matrix light-emitting apparatus illustrated in FIG. 3A and FIG. 3B includes a pixel portion 302, a circuit portion 303, a circuit portion 304a, and a circuit portion 304b.

Each of the circuit portion 303, the circuit portion 304a, and the circuit portion 304b can function as a scan line driver circuit (a gate driver) or a signal line driver circuit (a source driver), or may be a circuit that electrically connects the pixel portion 302 to an external gate driver or source driver.

A lead wiring 307 is provided over a first substrate 301. The lead wiring 307 is electrically connected to an FPC 308 that is an external input terminal. The FPC 308 transmits signals (e.g., a video signal, a clock signal, a start signal, and a reset signal) and a potential from the outside to the circuit portion 303, the circuit portion 304a, and the circuit portion 304b. The FPC 308 may be provided with a printed wiring board (PWB). The structure illustrated in FIG. 3A and FIG. 3B can also be referred to as a light-emitting module including a light-emitting device (or a light-emitting apparatus) and an FPC.

The pixel portion 302 includes a plurality of pixels each including an organic EL device 317, a transistor 311, and a transistor 312. As the organic EL device 317, the light-emitting device described in Embodiment 1 can be used. The transistor 312 is electrically connected to a first electrode 313 included in the organic EL device 317. The transistor 311 functions as a switching transistor. The transistor 312 functions as a current control transistor. Note that the number of transistors included in each pixel is not particularly limited and can be set appropriately as needed.

The circuit portion 303 includes a plurality of transistors, such as a transistor 309 and a transistor 310. The circuit portion 303 may be configured with a circuit including transistors having the same conductivity type (either n-channel transistors or p-channel transistors), or may be configured with a CMOS circuit including an n-channel transistor and a p-channel transistor. Furthermore, a driver circuit may be provided outside.

There is no particular limitation on the structure of the transistor included in the light-emitting apparatus of this embodiment. For example, a planar transistor, a staggered transistor, or an inverted staggered transistor can be used. A top-gate or a bottom-gate transistor structure may be employed. Alternatively, gates may be provided above and below a semiconductor layer where a channel is formed.

There is no particular limitation on the crystallinity of a semiconductor material used for the transistor, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be inhibited.

It is preferable that the semiconductor layer of the transistor contain a metal oxide (also referred to as an oxide semiconductor). Alternatively, the semiconductor layer of the transistor may contain silicon. Examples of silicon include amorphous silicon and crystalline silicon (e.g., low-temperature polysilicon and single crystal silicon).

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin.

It is particularly preferable to use an oxide containing indium (In), gallium (Ga), and zinc (Zn) (also referred to as IGZO) for the semiconductor layer.

In the case where the semiconductor layer is an In-M-Zn oxide, a sputtering target used for depositing the In-M-Zn oxide preferably has the atomic proportion of In higher than or equal to the atomic proportion of M. Examples of the atomic ratio of the metal elements in such a sputtering target include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:6, In:M:Zn=5:1:7, In:M:Zn=5:1:8, In:M:Zn=6:1:6, and In:M:Zn=5:2:5.

The transistors included in the circuit portion 303, the circuit portion 304a, and the circuit portion 304b and the transistors included in the pixel portion 302 may have the same structure or different structures. A plurality of transistors included in the circuit portion 303, the circuit portion 304a, and the circuit portion 304b may have the same structure or two or more kinds of structures. Similarly, a plurality of transistors included in the pixel portion 302 may have the same structure or two or more kinds of structures.

An end portion of the first electrode 313 is covered with an insulating layer 314. For the insulating layer 314, an organic compound such as a negative photosensitive resin or a positive photosensitive resin (acrylic resin), or an inorganic compound such as silicon oxide, silicon oxynitride, or silicon nitride can be used. An upper end portion or a lower end portion of the insulating layer 314 preferably has a curved surface with curvature. In that case, favorable coverage with a film formed over the insulating layer 314 can be obtained.

An EL layer 315 is provided over the first electrode 313, and a second electrode 316 is provided over the EL layer 315. The EL layer 315 includes alight-emitting layer, a hole-injection layer, a hole-transport layer, an electron-transport layer, an electron-injection layer, a charge-generation layer, and the like.

The plurality of transistors and the plurality of organic EL devices 317 are sealed by the first substrate 301, a second substrate 306, and a sealant 305. A space 318 surrounded by the first substrate 301, the second substrate 306, and the sealant 305 may be filled with an inert gas (e.g., nitrogen or argon) or an organic substance (including the sealant 305).

An epoxy resin or glass frit can be used for the sealant 305. A material that transmits moisture and oxygen as little as possible is preferably used for the sealant 305. In the case where glass frit is used for the sealant, the first substrate 301 and the second substrate 306 are preferably glass substrates in terms of adhesion.

This embodiment can be combined with the other embodiments as appropriate.

### Embodiment 3

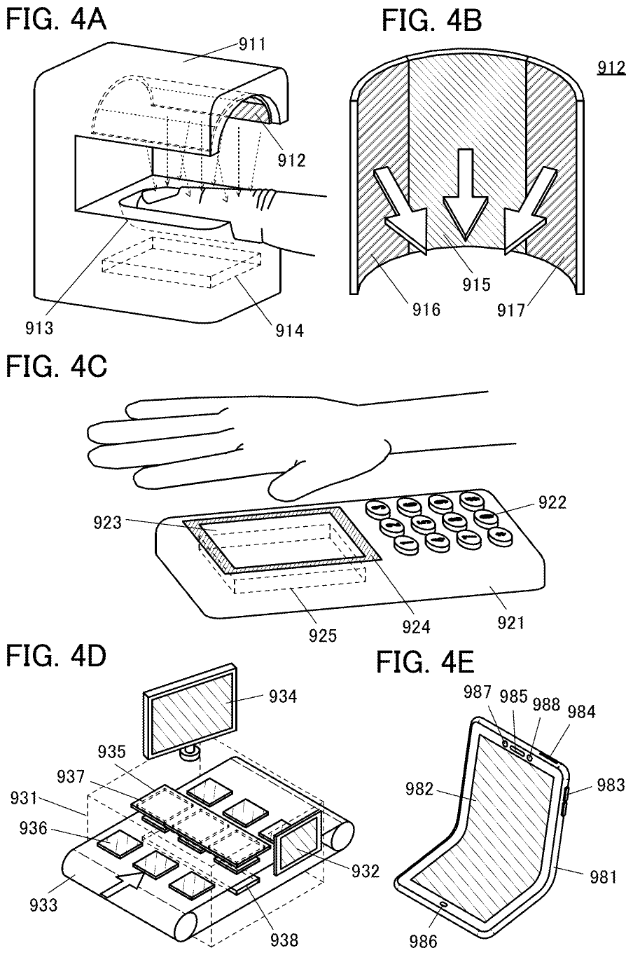

In this embodiment, electronic devices in which the light-emitting device of one embodiment of the present invention can be used will be described with reference to FIG. 4.

The light-emitting device of one embodiment of the present invention emits both near-infrared light and visible light. Accordingly, the user can see visible light while authentication, analysis, diagnosis, or the like performed with near-infrared light is being carried out in the electronic device. In general, near-infrared light emission needs to be identified with a dedicated measurement apparatus or the like; however, in the case of the electronic device of one embodiment of the present invention, the user himself/herself can confirm whether authentication, analysis, diagnosis, or the like performed with near-infrared light is carried out in the electronic device in real time, depending on whether or not the user can see visible light. In addition, the emission color of the visible light is sometimes changed in accordance with the magnitude of radiance. Therefore, the emission intensity of the near-infrared light can be estimated by the emission intensity or the color of the visible light. These cause effects such as inhibiting a finger from being off from the electronic device by mistake during biometric authentication or making it easier to notice a failure in biometric authentication in the electronic device, for example. Since the emission intensity of the visible light is sufficiently lower than the emission intensity of the near-infrared light, the visible light emitted by the light-emitting device can be inhibited from becoming noise in authentication, analysis, diagnosis, or the like performed with near-infrared light. Thus, the accuracy of authentication, analysis, diagnosis, or the like can be improved.

FIG. 4A illustrates a biometric authentication apparatus for sensing a finger vein which includes a housing 911, a light source 912, a sensing stage 913, and the like. By putting a finger on the sensing stage 913, an image of a vein pattern can be taken. The light source 912 that emits near-infrared light is provided above the sensing stage 913, and an imaging device 914 is provided under the sensing stage 913. The sensing stage 913 is formed of a material that transmits near-infrared light, and near-infrared light that is emitted from the light source 912 and passes through the finger can be captured by the imaging device 914. Note that an optical system may be provided between the sensing stage 913 and the imaging device 914. The structure of the apparatus described above can also be used for a biometric authentication apparatus for sensing a palm vein.

The light-emitting device of one embodiment of the present invention can be used for the light source 912. The light-emitting device of one embodiment of the present invention can be provided to be curved and can emit light uniformly toward a target. In particular, the light-emitting device preferably emits near-infrared light with the maximum peak intensity at a wavelength from 760 nm to 900 nm. An image is formed from received light that has passed through the finger, palm, or the like, whereby the position of the vein can be detected. This action can be utilized for biometric authentication. A combination with a global shutter system enables highly accurate sensing even for a moving target.

The light source 912 can include a plurality of light-emitting portions, such as light-emitting portions 915, 916, and 917 illustrated in FIG. 4B. The light-emitting portions 915, 916, and 917 may emit light having different wavelengths, or can emit light at different timings. Thus, by changing wavelengths and angles of light to be delivered, different images can be taken successively; hence, high level of security can be achieved using a plurality of images for the authentication.

FIG. 4C illustrates a biometric authentication apparatus for sensing a palm vein which includes a housing 921, operation buttons 922, a sensing portion 923, a light source 924 that emits near-infrared light, and the like. By holding a hand over the sensing portion 923, a palm vein pattern can be recognized. Furthermore, a security code or the like can be input with the operation buttons. The light source 924 is provided around the sensing portion 923 and irradiates a target (a hand) with light. Then, light reflected by the target enters the sensing portion 923. The light-emitting device of one embodiment of the present invention can be used for the light source 924. An imaging device 925 is provided directly under the sensing portion 923 and can capture an image of the target (an image of the whole hand). Note that an optical system may be provided between the sensing portion 923 and the imaging device 925. The structure of the apparatus described above can also be used for a biometric authentication apparatus for sensing a finger vein.

FIG. 4D illustrates a non-destructive testing apparatus which includes a housing 931, an operation panel 932, a transport mechanism 933, a monitor 934, a sensing unit 935, a light source 938 that emits near-infrared light, and the like. The light-emitting device of one embodiment of the present invention can be used for the light source 938. Test specimens 936 are transported to be the position directly under the sensing unit 935 by the transport mechanism 933. The test specimen 936 is irradiated with near-infrared light from the light source 938, and an image of the light passing therethrough is taken by an imaging device 937 provided in the sensing unit 935. The taken image is displayed on the monitor 934. After that, the test specimens 936 are transported to the exit of the housing 931, and a defective member is separately collected. Imaging with the use of near-infrared light enables non-destructive and high-speed sensing of defective elements inside the test specimen, such as defects and foreign substances.

FIG. 4E illustrates a mobile phone which includes a housing 981, a display portion 982, an operation button 983, an external connection port 984, a speaker 985, a microphone 986, a first camera 987, a second camera 988, and the like. The display portion 982 of the mobile phone includes a touch sensor. The housing 981 and the display portion 982 have flexibility. All operations including making a call and inputting text can be performed by touch on the display portion 982 with a finger, a stylus, or the like. The first camera 987 can take a visible light image, and the second camera 988 can take an infrared light image (a near-infrared light image). The mobile phone or the display portion 982 illustrated in FIG. 4E may include the light-emitting device of one embodiment of the present invention.

This embodiment can be combined with the other embodiments as appropriate.

### Example 1

In this example, light-emitting devices of one embodiment of the present invention were fabricated, and evaluation results thereof are described.

In this example, a device 1 to which one embodiment of the present invention is applied and a comparative device 2 for comparison were fabricated as light-emitting devices, and evaluation results thereof are described.

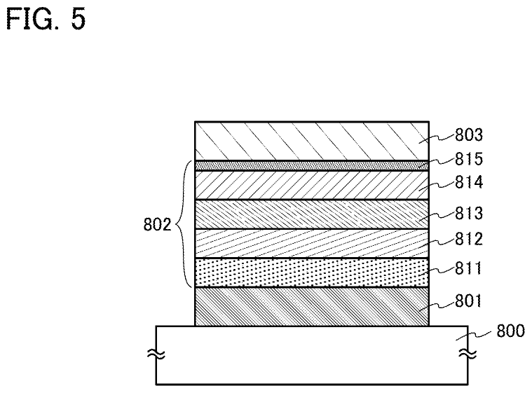

FIG. 5 illustrates the structure of the light-emitting device 1 and the comparative device 2 used in this example, and Table 1 shows specific components. The structural formulae of materials used in this example are shown below.

TABLE 1

| | First | Hole-injection | Hole-transport | Light-emitting | Electron-transport | | Electron-injection | Second |
|---|---|---|---|---|---|---|---|---|
| | electrode | layer | layer | layer | layer | | layer | electrode |
| | 801 | 811 | 812 | 813 | 814 | | 815 | 803 |
| Device 1 | ITSO | DBT3P-IIMoOx | PCBBiF | * | 2mDBTBPDBq-II | NBphen | LiF | Al |
| | (110 nm) | (2:1 60 nm) | (20 nm) | | (20 nm) | (70 nm) | (1 nm) | (200 nm) |
| Comparative | ITSO | DBT3P-IIMoOx | PCBBiF | ** | 2,8mDBtP2Bfqn | NBphen | LiF | Al |
| device 2 | (70 nm) | (2:1 120 nm) | (20 nm) | | (20 nm) | (70 nm) | (1 nm) | (200 nm) |

* 2mDBTBPDBq-II:PCBBiF:[Ir(dmdpbq)₂(dpm)] (0.7:0.3:0.1 40 nm)
** 2,8mDBtP2Bfqn:m-MTDATA:[Ir(dmdpbq)₂(dpm)] (0.7:0.3:0.1 40 nm)

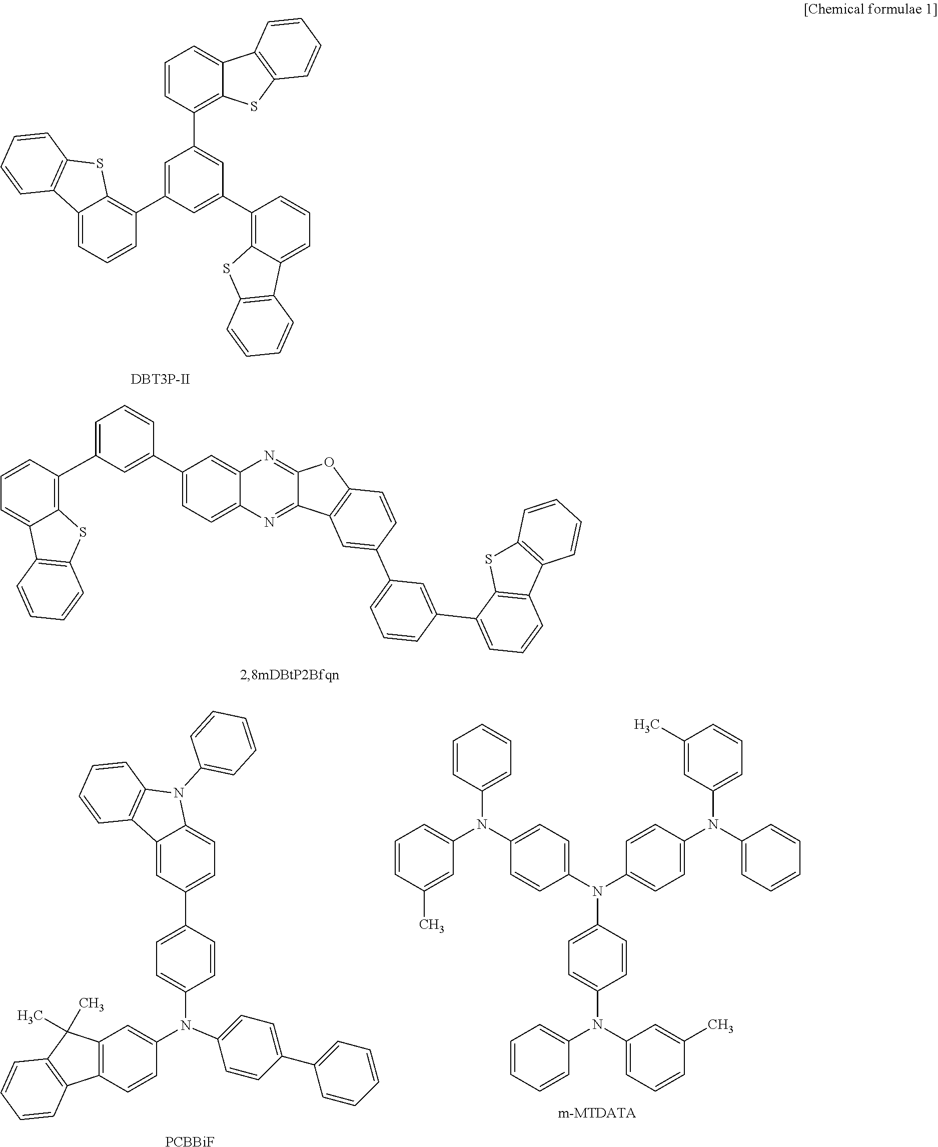

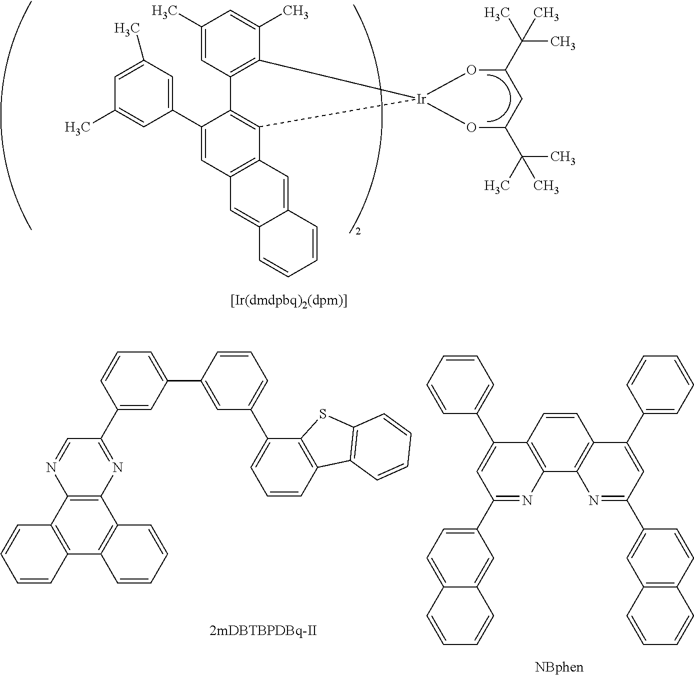

### <<Fabrication of Light-Emitting Devices>>

The device 1 and the comparative device 2 described in this example each have a structure as illustrated in FIG. 5, in which a first electrode 801 is formed over a substrate 800; as an EL layer 802, a hole-injection layer 811, a hole-transport layer 812, a light-emitting layer 813, an electron-transport layer 814, and an electron-injection layer 815 are stacked in this order over the first electrode 801; and a second electrode 803 is stacked over the electron-injection layer 815.

First, the first electrode 801 was formed over the substrate 800. The electrode area was set to 4 mm² (2 mm×2 mm). A glass substrate was used as the substrate 800. The first electrode 801 was formed by a sputtering method using indium tin oxide containing silicon oxide (ITSO). The thickness of the first electrode 801 was set to 110 nm in the device 1 and 70 nm in the comparative device 2. In this example, the first electrode 801 functions as an anode.

As pretreatment, a surface of the substrate was washed with water, baking was performed at 200° C. for one hour, and then UV ozone treatment was performed for 370 seconds. After that, the substrate was transferred into a vacuum evaporation apparatus in which the pressure was reduced to about 1×10⁻⁴ Pa, vacuum baking at 170° C. for 30 minutes was performed in a heating chamber in the vacuum evaporation apparatus, and then the substrate was naturally cooled down for about 30 minutes.

Next, the hole-injection layer 811 was formed over the first electrode 801. For the formation of the hole-injection layer 811, the pressure in the vacuum evaporation apparatus was reduced to about 1×10⁻⁴ Pa, and then 1,3,5-tri(dibenzothiophen-4-yl)benzene (abbreviation: DBT3P-II) and molybdenum oxide were co-evaporated such that DBT3P-II:molybdenum oxide=2:1 (weight ratio). The thickness of the hole-injection layer 811 was set to 60 nm in the device 1 and 120 nm in the comparative device 2.

Then, the hole-transport layer 812 was formed over the hole-injection layer 811. The hole-transport layer 812 was formed to a thickness of 20 nm by evaporation using N-(1,1′-biphenyl-4-yl)-N-[4-(9-phenyl-9H-carbazol-3-yl)phenyl]-9,9-dimethyl-9H-fluoren-2-amine (abbreviation: PCBBiF).

Next, the light-emitting layer 813 was formed over the hole-transport layer 812.

In the device 1, co-evaporation was performed using 2-[3′-(dibenzothiophen-4-yl)biphenyl-3-yl]dibenzo[f,h]quinoxaline (abbreviation: 2mDBTBPDBq-II) and PCBBiF as host materials and bis{4,6-dimethyl-2-[3-(3,5-dimethylphenyl)-2-benzo[g]quinoxalinyl-κN]phenyl-κC}(2,2,6,6-tetramethyl-3,5-heptanedionato-κ²O,O′)iridium(III) (abbreviation: [Ir(dmdpbq)₂(dpm)]) as a guest material (a phosphorescent material) such that the weight ratio was 2mDBTBPDBq-II:PCBBiF:[Ir(dmdpbq)₂(dpm)]=0.7:0.3:0.1. The thickness of the light-emitting layer 813 was set to 40 nm.

In the comparative device 2, co-evaporation was performed using 2,8-bis[3-(dibenzothiophen-4-yl)phenyl]benzofuro[2,3-b]quinoxaline (abbreviation: 2,8mDBtP2Bfqn) and 4,4′,4″-tris[N-(3-methylphenyl)-N-phenylamino]triphenylamine (abbreviation: m-MTDATA) as host materials and [Ir(dmdpbq)₂(dpm)] as a guest material (phosphorescent material) such that the weight ratio was 2,8mDBtP2Bfqn:m-MTDATA:[Ir(dmdpbq)₂(dpm)]=0.7:0.3:0.1. The thickness of the light-emitting layer 813 was set to 40 nm.

Next, the electron-transport layer 814 was formed over the light-emitting layer 813.

The electron-transport layer 814 of the device 1 was formed by sequential evaporation such that the thickness of 2mDBTBPDBq-II was 20 nm and the thickness of 9-bis(naphthalen-2-yl)-4,7-diphenyl-1,10-phenanthroline (abbreviation: NBphen) was 70 nm.

The electron-transport layer 814 of the comparative device 2 was formed by sequential evaporation such that the thickness of 2,8mDBtP2Bfqn was 20 nm and the thickness of NBphen was 70 nm.

Then, the electron-injection layer 815 was formed over the electron-transport layer 814. The electron-injection layer 815 was formed to a thickness of 1 nm by evaporation using lithium fluoride (LiF).

After that, the second electrode 803 was formed over the electron-injection layer 815. The second electrode 803 was formed to a thickness of 200 nm by an evaporation method using aluminum. In this example, the second electrode 803 functions as a cathode.

Through the above steps, the light-emitting devices in each of which the EL layer 802 was provided between the pair of electrodes over the substrate 800 were fabricated. The hole-injection layer 811, the hole-transport layer 812, the light-emitting layer 813, the electron-transport layer 814, and the electron-injection layer 815 described in the above steps are functional layers forming the EL layer in one embodiment of the present invention. Furthermore, in all the evaporation steps in the above fabrication method, an evaporation method by a resistance-heating method was used.

The light-emitting device fabricated as described above was sealed using a different substrate (not illustrated). At the time of the sealing using the different substrate (not illustrated), the different substrate (not illustrated) on which an adhesive that is solidified by ultraviolet light was applied was fixed onto the substrate 800 in a glove box containing a nitrogen atmosphere, and the substrates were bonded to each other such that the adhesive was attached to the periphery of the light-emitting device formed over the substrate 800. At the time of the sealing, the adhesive was irradiated with 365-nm ultraviolet light at 6 J/cm² to be solidified, and the adhesive was subjected to heat treatment at 80° C. for one hour to be stabilized.

### <<Operation Characteristics of Light-Emitting Devices>>

Operation characteristics of Device 1 and Comparative Device 2 were measured. Note that the measurement was carried out at room temperature (in an atmosphere maintained at 25° C.).

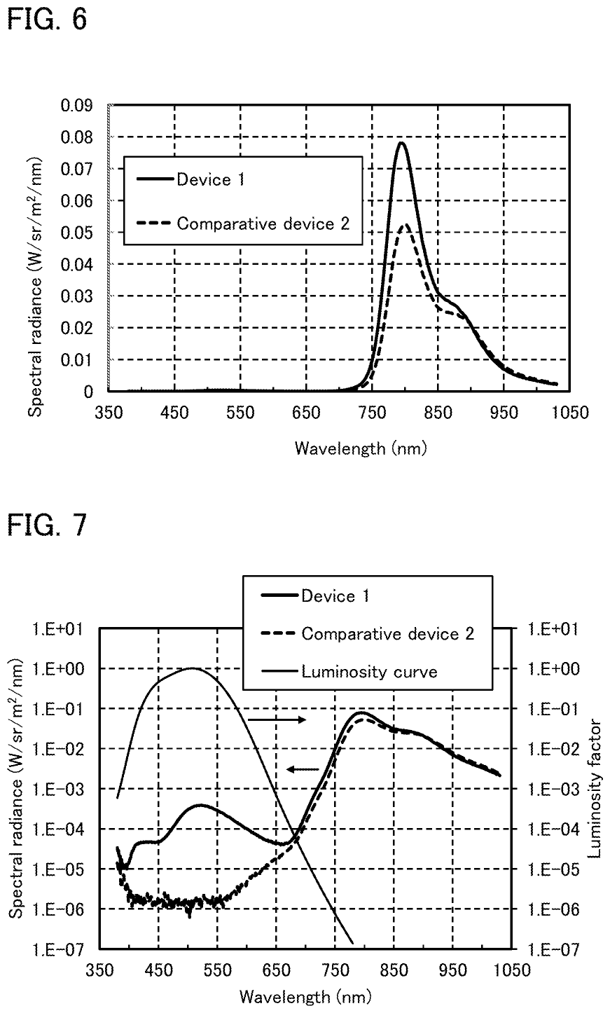

FIG. 6 and FIG. 7 show emission spectra obtained when current flowed through the device 1 and the comparative device 2 at a current density of 50 mA/cm². Emission spectra in a wavelength range of greater than or equal to 380 nm and less than or equal to 749 nm correspond to measurement results obtained with a spectroradiometer (SR-UL1R manufactured by TOPCON TECHNOHOUSE CORPORATION) and emission spectra in a wavelength range of greater than or equal to 750 nm and less than or equal to 1030 nm correspond to measurement results obtained with a near-infrared spectroradiometer (SR-NIR manufactured by TOPCON TECHNOHOUSE CORPORATION). FIG. 7 is different from FIG. 6 in that the vertical axis is on a logarithmic scale. Furthermore, FIG. 7 also shows a luminosity curve based on scotopic luminosity (CIE (1951) Scotopic V′(λ)).

Table 2 shows the initial values of main characteristics of the device 1 and the comparative device 2 at a current of 2 mA (a current density of 50 mA/cm²). Note that the radiant flux and the external quantum efficiency were calculated using the radiance, assuming that the light-emitting devices had Lambertian light-distribution characteristics.

TABLE 2

| | | | Current | | | Luminance/ | Radiant | External quantum |
|---|---|---|---|---|---|---|---|---|
| | Voltage | Current | density | Luminance | Radiance | Radiance | flux | efficiency |
| | (V) | (mA) | (mA/cm²) | (cd/m²) | (W/sr/m²) | (cd · sr/W) | (mW) | (%) |
| Device 1 | 5.8 | 2.0 | 50 | 16 | 7.5 | 2.1 | 0.09 | 3.1 |
| Comparative | 6.5 | 2.0 | 50 | 0.28 | 5.8 | 0.05 | 0.07 | 2.5 |
| device 2 | | | | | | | | |

As shown in FIG. 6, the maximum peak wavelength in the emission spectrum of the device 1 was 793 nm and the maximum peak wavelength in the emission spectrum of the comparative device 2 was 801 nm, indicating that both the devices emitted near-infrared light originating from [Ir(dmdpbq)₂(dpm)] contained in the light-emitting layer 813.

The rising wavelength of the maximum peak on a short wavelength side was 751 nm in the emission spectrum of the device 1 shown in FIG. 6. The rising wavelength of the maximum peak on a short wavelength side was 754 nm in the emission spectrum of the comparative device 2. It was found that the device 1 and the comparative device 2 each had a sufficiently long rising wavelength of the maximum peak on the short wavelength side.

As shown in FIG. 7, it was confirmed that the emission spectrum of the device 1 had a relatively high emission peak (a peak wavelength of 523 nm (2.37 eV)) in the visible light wavelength range. It was found from comparison with the luminosity curve that the light emitted by the device 1 included light in a wavelength range of a high luminosity factor of visible light. In contrast, the comparative device 2 had a lower spectral radiance in the visible light wavelength range than the device 1. The maximum peak wavelength in the visible light of the comparative device 2 was 638 nm (1.94 eV), and the emission spectrum of the device 1 had a peak in a wavelength range of a low luminosity factor of visible light. Thus, it was found that the device 1 emitted visible light in a wavelength range of a high luminosity factor and had high emission intensity in the wavelength range of the visible light, as compared to the comparative device 2. Note that the maximum peak (emission peak of near-infrared light) in the emission spectrum of the device 1 has intensity greater than or equal to 10 times that of the emission peak of the visible light; thus, the device 1 mainly emits near-infrared light. As described above, it was found that the device 1 emitted near-infrared light and the visible light emitted by the device 1 was easily seen.

As shown in Table 2, the luminance/radiance of the device 1 was 2.1 and the luminance/radiance of the comparative device 2 was 0.05. Thus, it was found that the emission intensity of visible light was higher than the emission intensity of near-infrared light in the device 1. This also suggests that the device 1 emits near-infrared light and the visible light emitted by the device 1 is easily seen. In contrast, the comparison device 2 emits near-infrared light and the visible light emitted by the comparative device 2 is less likely to be seen.

As shown in Table 2, the external quantum efficiency of the device 1 was 3.1%. The value can be regarded as high for the external quantum efficiency of a light-emitting device emitting near-infrared light. Note that the external quantum efficiency of the device 1 was calculated from the measurement result in a wavelength range of greater than or equal to 600 nm and less than or equal to 1030 nm, which was obtained with a near-infrared spectroradiometer (SR-NIR manufactured by TOPCON TECHNOHOUSE CORPORATION). The range is a region having longer wavelengths than the emission peak in the visible light region of the device 1. The external quantum efficiency can be regarded as external quantum efficiency calculated mainly from the near-infrared light of the device 1.

A mixed film A of the two host materials used in the device 1 and a mixed film B of the two host materials used in the comparative device 2 were formed, and emission spectra (PL spectra) of the films were measured.

The mixed film A was formed over a quartz substrate to have a thickness of 50 nm by co-evaporation of 2mDBTBPDBq-II and PCBBiF in 2mDBTBPDBq-II:PCBBiF=0.7:0.3 (weight ratio). Here, 2mDBTBPDBq-II and PCBBiF form an exciplex in combination.

The mixed film B was formed over a quartz substrate to have a thickness of 50 nm by co-evaporation of 2,8mDBtP2Bfqn and m-MTDATA in 2,8mDBtP2Bfqn:m-MTDATA=0.7:0.3 (weight ratio). Here, 2,8mDBtP2Bfqn and m-MTDATA form an exciplex in combination.

Table 3 shows the HOMO levels and the LUMO levels of the host materials. Note that the HOMO levels and the LUMO levels were derived from the electrochemical characteristics (the reduction potentials and the oxidation potentials) of the materials that were measured by cyclic voltammetry (CV). Table 3 also shows the HOMO level and the LUMO level of the guest material used in the device 1 and the comparative device 2.

TABLE 3

| | | HOMO (eV) | LUMO (eV) |
|---|---|---|---|
| Device1 | 2mDBTBPDBq-II | −6.22 | −2.94 |
| Mixed film A | PCBBiF | −5.36 | −2.00 |
| Comparative device 2 | 2,8mDBtP2Bfqn | −6.20 | −3.31 |
| Mixed film B | m-MTDATA | −4.98 | −2.22 |
| Guest material | Ir(dmdpbq)₂(dpm) | −5.54 | −3.49 |

Next, the HOMO levels and the LUMO levels of the two host materials used in the device 1 and the mixed film A are described with Table 3. It is found that the HOMO level of PCBBiF is higher than both the HOMO level of [Ir(dmdpbq)₂(dpm)] and the HOMO level of 2mDBTBPDBq-II. Specifically, the HOMO level (−5.36 eV) of PCBBiF is higher than the HOMO level (−5.54 eV) of [Ir(dmdpbq)₂(dpm)] by 0.18 eV. In addition, the difference between the HOMO level (−5.36 eV) of PCBBiF and the LUMO level (−2.94 eV) of 2mDBTBPDBq-II is 2.42 eV, which is larger than the difference (2.05 eV) between the HOMO level (−5.54 eV) and the LUMO level (−3.49 eV) of [Ir(dmdpbq)₂(dpm)].

Next, the HOMO levels and the LUMO levels of the two host materials used in the comparative device 2 and the mixed film B are described with Table 3. It is found that the HOMO level of m-MTDATA is higher than both the HOMO level of [Ir(dmdpbq)₂(dpm)] and the HOMO level of 2,8mDBtP2Bfqn. Specifically, the HOMO level (−4.98 eV) of m-MTDATA is higher than the HOMO level (−5.54 eV) of [Ir(dmdpbq)₂(dpm)] by 0.56 eV. In addition, the difference between the HOMO level (−4.98 eV) of m-MTDATA and the LUMO level (−3.31 eV) of 2,8mDBtP2Bfqn is 1.67 eV, which is smaller than a difference (2.05 eV) between the HOMO level (−5.54 eV) and the LUMO level (−3.49 eV) of [Ir(dmdpbq)₂(dpm)].

The PL spectra were measured with a fluorophotometer (FS920 manufactured by Hamamatsu Photonics K.K.) at room temperature.

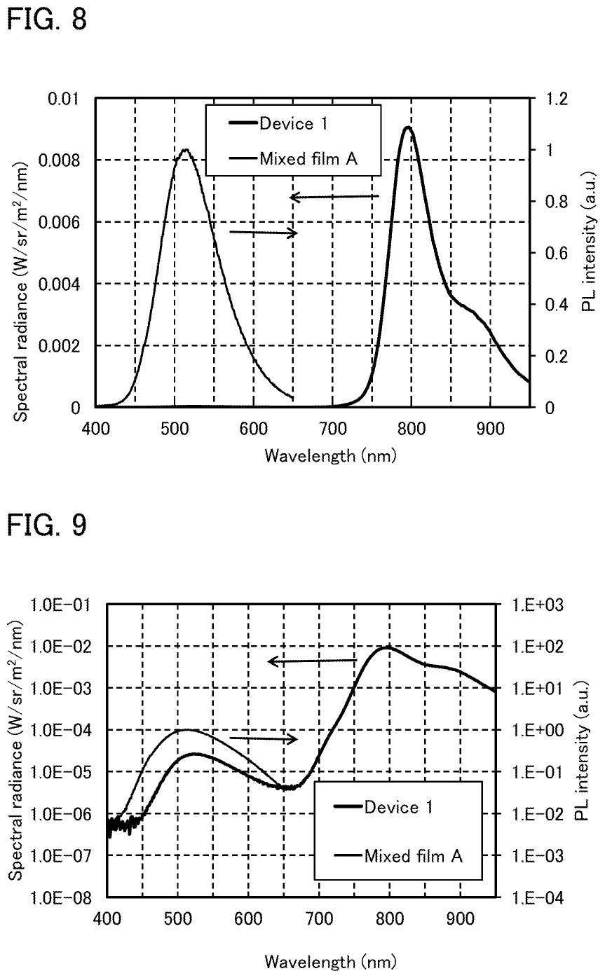

FIG. 8 and FIG. 9 show the PL spectrum of the mixed film A and the emission spectrum of the device 1 (similar to that in FIG. 6 and FIG. 7). FIG. 9 is different from FIG. 8 in that the vertical axis is on a logarithmic scale.

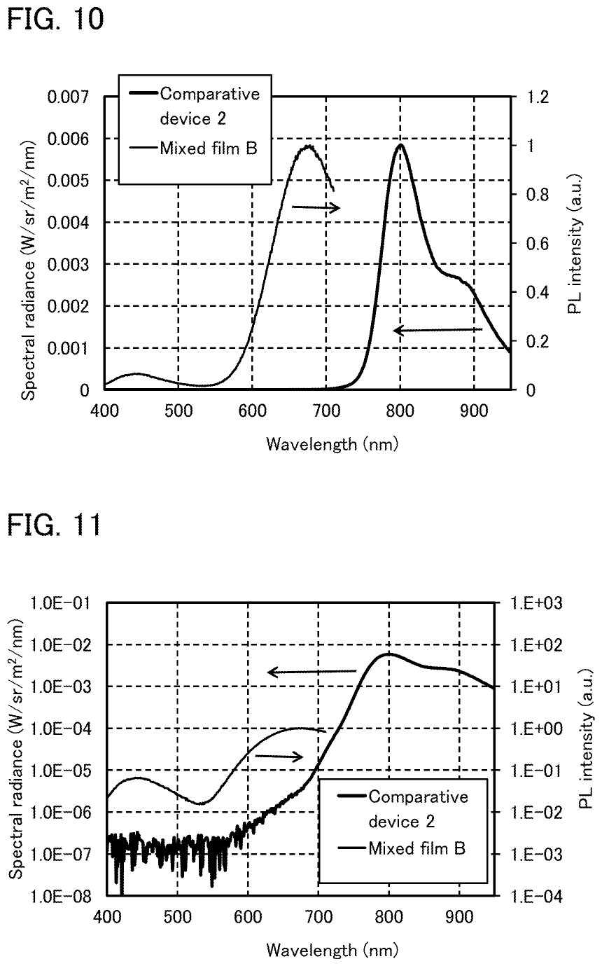

FIG. 10 and FIG. 11 show the PL spectrum of the mixed film B and the emission spectrum of the comparative device 2 (similar to that in FIG. 6). FIG. 11 is different from FIG. 10 in that the vertical axis is on a logarithmic scale.

As shown in FIG. 8, the maximum peak wavelength in the PL spectrum of the mixed film A was 516 nm. From the difference between the HOMO level of PCBBiF and the LUMO level of 2mDBTBPDBq-II, it can be said that light emission of the mixed film A is light emission originating from the exciplex formed by these two materials.

As shown in FIG. 10, the maximum peak wavelength in the PL spectrum of the mixed film B was 678 nm. From the difference between the HOMO level of m-MTDATA and the LUMO level of 2,8mDBtP2Bfqn, it can be said that light emission of the mixed film B is light emission originating from the exciplex formed by these two materials.

Since the emission peak wavelength in the visible light range of the device 1 is close to the maximum peak wavelength in the PL spectrum of the mixed film A, it is demonstrated that the visible light emission observed in the device 1 was light emission originating the exciplex formed by the two host materials.

The maximum peak wavelength in the PL spectrum of the mixed film A is included in a wavelength range of a high luminosity factor. Thus, light originating from the exciplex formed by the two host materials used in the mixed film A has a high luminosity factor. Therefore, the device 1 is a light-emitting device in which visible light originating from an exciplex is easy to see

As described above, the difference between the HOMO level of PCBBiF and the LUMO level of 2mDBTBPDBq-II, which were used in the mixed film A, is larger than the difference between the HOMO level and the LUMO level of [Ir(dmdpbq)₂(dpm)] and is included in the range of a high luminosity factor. Accordingly, the luminosity factor of light emission originating from an exciplex formed by these two materials can be high.

As described above, it was found from this example that by making light emitted by an exciplex formed by two host materials have a wavelength of a high luminosity factor, a light-emitting device that emits near-infrared light and emits visible light easily seen can be fabricated.

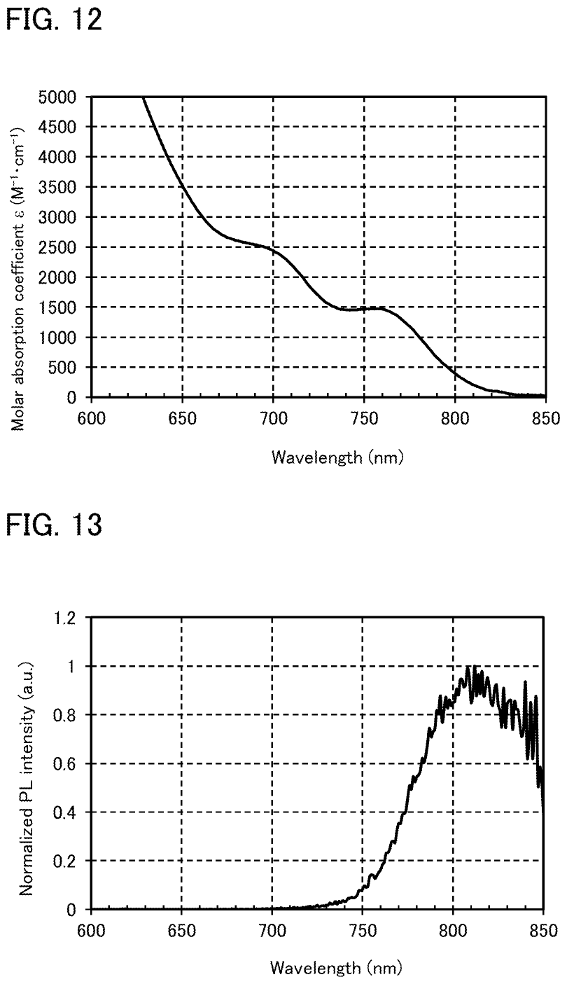

Next, FIG. 12 and FIG. 13 show the measurement results of an ultraviolet-visible absorption spectrum (hereinafter simply referred to as an “absorption spectrum”) and an emission spectrum (PL spectrum) of [Ir(dmdpbq)₂(dpm)] in a dichloromethane solution.

The measurement of the absorption spectrum was conducted at room temperature, for which an ultraviolet-visible spectrophotometer (V550 type manufactured by JASCO Corporation) was used and the dichloromethane solution (0.010 mmol/L) was put into a quartz cell. The measurement of the emission spectrum was conducted at room temperature, for which a fluorescence spectrophotometer (FS920 manufactured by Hamamatsu Photonics K.K.) was used and the deoxygenated dichloromethane solution (0.010 mmol/L) was put and hermetically sealed into a quartz cell in a nitrogen atmosphere.

The absorption spectrum shown in FIG. 12 is the results obtained in such a way that the absorption spectrum measured by putting only dichloromethane in a quartz cell was subtracted from the absorption spectrum measured by putting the dichloromethane solution (0.010 mmol/L) in a quartz cell.

It was found from FIG. 12 that a longest-wavelength-side (lowest-energy-side) absorption edge of [Ir(dmdpbq)₂(dpm)] was at 810 nm (1.53 eV). As described above, the maximum peak in the PL spectrum of the mixed film A was at 516 nm (2.40 eV). The results showed that the maximum peak in the emission spectrum of the exciplex in the device 1 had a shorter wavelength (larger energy) than the absorption edge.

It was also found from FIG. 12 that a peak of a longest-wavelength-side (lowest-energy-side) absorption band of [Ir(dmdpbq)₂(dpm)] was at 757 nm (1.64 eV). The result showed that the maximum peak in the emission spectrum of the exciplex in the device 1 was on the shorter wavelength side (higher energy side) than the peak of the absorption band. Specifically, the energy of the maximum peak in the emission spectrum of the exciplex in the device 1 was higher than the energy of the peak of the absorption band by 0.76 eV.

As shown in FIG. 13, [Ir(dmdpbq)₂(dpm)] had an emission peak at 807 nm (1.54 eV), and near-infrared light was observed from the dichloromethane solution. The emission peak rose at 754 nm (1.64 eV).

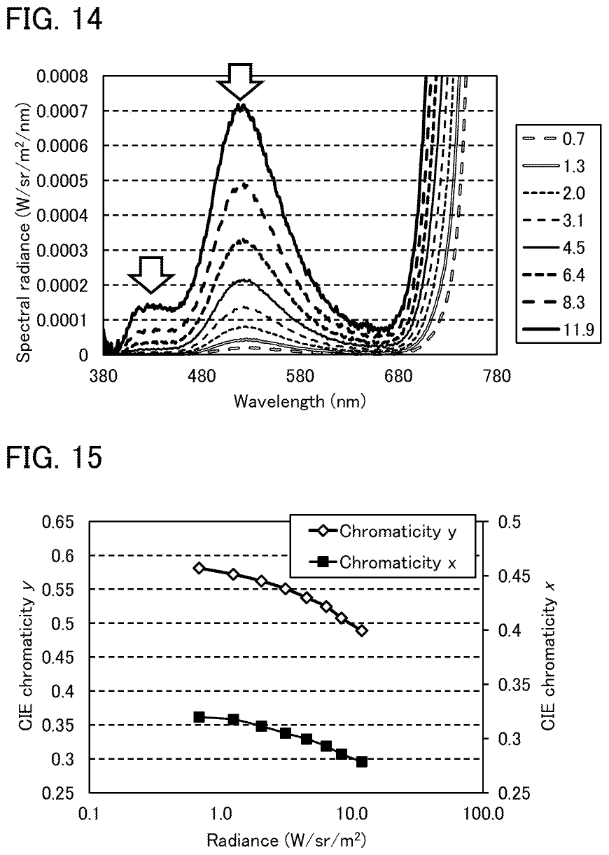

FIG. 14 shows changes in spectral radiance in accordance with the radiance of the device 1. FIG. 14 shows spectral radiance (unit: W/sr/m²/nm) at the time when the radiance (unit: W/sr/m²) was 0.7, 1.3, 2.0, 3.1, 4.5, 6.4, 8.3, and 11.9. In FIG. 14, emission spectra in a wavelength range of greater than or equal to 380 nm and less than or equal to 749 nm correspond to measurement results obtained with a spectroradiometer (SR-UL1R manufactured by TECHNOHOUSE CORPORATION), and emission spectra in a wavelength range of greater than or equal to 750 nm and less than or equal to 1030 nm correspond to measurement results obtained with a near-infrared spectroradiometer (SR-NIR manufactured by TOPCON TECHNOHOUSE CORPORATION).

FIG. 15 shows the relationship between the radiance and the CIE chromaticity coordinates (x, y) of the device 1. As the values of chromaticity in FIG. 15, measurement results of a wavelength range of greater than or equal to 380 nm and less than or equal to 780 nm that were obtained with a spectroradiometer (SR-UL1R manufactured by TOPCON TECHNOHOUSE CORPORATION) were used. As the values of radiance in FIG. 14 and FIG. 15, measurement results of a wavelength range of greater than or equal to 600 nm and less than or equal to 1030 nm that were obtained with a near-infrared spectroradiometer (SR-NIR manufactured by TOPCON TECHNOHOUSE CORPORATION) were used.

Comparison between two portions indicated by arrows in FIG. 14 showed that the intensity ratio of light emission originating from the host material and light emission originating from the exciplex varied depending on the radiance.

As shown in FIG. 15, the chromaticity x and the chromaticity y both decreased as the radiance increased. Specifically, the color was changed from green to white. The results revealed that it is possible to estimate the magnitude of radiance by checking the emission color of visible light of the device 1.

<<Reliability Test on Device 1>>

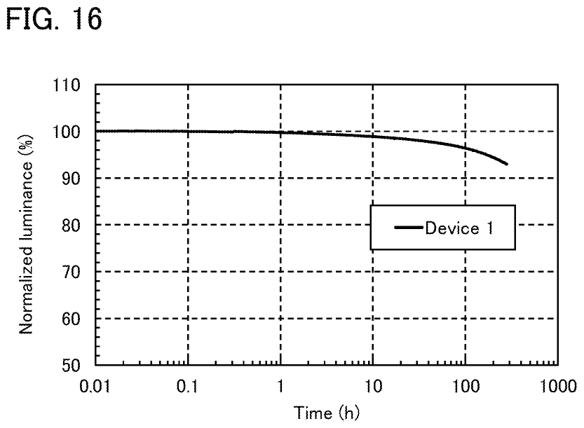

Next, a reliability test was performed on the device 1. FIG. 16 shows the results of the reliability test. In FIG. 16, the vertical axis represents normalized luminance (%) with an initial luminance of 100%, and the horizontal axis represents driving time (h). In the reliability test, the device 1 was driven at a current density of 75 mA/cm².

As shown in FIG. 16, the device 1 had a small degradation in the luminance, exhibiting high reliability. In particular, the device 1 was found to have high reliability for a light-emitting device in which not only a guest material but also an exciplex emits light. This presumably relates to the low T₁ level of the guest material. Specifically, side reaction such as reaction between the excitation state of the host material and the excitation state of the guest material is less likely to occur because the excitation level of the guest material is low and the excitation state is stable, which presumably increases the reliability of the light-emitting device.

### Example 2

In this example, light-emitting devices of one embodiment of the present invention were fabricated, and evaluation results thereof are described.

This example shows evaluation results of four kinds of devices that were fabricated as the light-emitting devices of one embodiment of the present invention and had different guest material concentrations in the light-emitting layers 813.

FIG. 5 illustrates the structure of the light-emitting devices used in this example, and Table 4 shows specific components. The structural formula of a material used in this example is shown below. Note that the chemical formulae of the materials shown above are not shown.

TABLE 4

| First | Hole-injection | Hole-transport | Light-emitting | | | Electron-injection | Second |
|---|---|---|---|---|---|---|---|
| electrode | layer | layer | layer | Electron-transport layer | | layer | electrode |
| 801 | 811 | 812 | 813 | 814 | | 815 | 803 |
| ITSO | PCBBiF:ALD-MP001Q | PCBBiF | * | 9mDBtBPNfpr | NBphen | LiF | Al |
| (70 nm) | (1:0.1 10 nm) | (130 nm) | | (20 nm) | (60 nm) | (1 nm) | (200 nm) |

* 9mDBtBPNfpr:PCBBiF:[Ir(dmdpbq)₂(dpm)] (0.7:0.3:X 10 nm) X = 0.01, 0.025, 0.05, or 0.1)

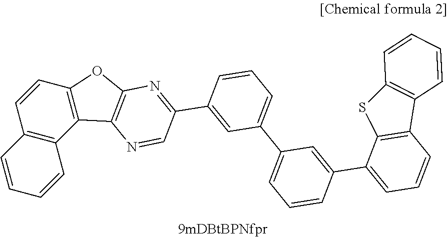 [SMILES: c1cc(-c2cccc(-c3cccc4c3sc3ccccc34)c2)cc(-c2cnc3c(n2)oc2ccc4ccccc4c23)c1]

### <<Fabrication of Light-Emitting Devices>>

The light-emitting devices fabricated in this example each have a structure similar to that of the light-emitting device fabricated in Example 1 (FIG. 5).

First, the first electrode 801 was formed over the substrate 800. The electrode area was set to 4 mm² (2 mm×2 mm). A glass substrate was used as the substrate 800. The first electrode 801 was formed by a sputtering method using indium tin oxide containing silicon oxide (ITSO). The thickness of the first electrode 801 was set to 70 nm. In this example, the first electrode 801 functions as an anode.

As pretreatment, a surface of the substrate was washed with water, baking was performed at 200° C. for one hour, and then UV ozone treatment was performed for 370 seconds. After that, the substrate was transferred into a vacuum evaporation apparatus in which the pressure was reduced to about 1×10⁻⁴ Pa, vacuum baking at 170° C. for 30 minutes was performed in a heating chamber in the vacuum evaporation apparatus, and then the substrate was naturally cooled down for about 30 minutes.

Next, the hole-injection layer 811 was formed over the first electrode 801. For the formation of the hole-injection layer 811, the pressure in the vacuum evaporation apparatus was reduced to about 1×10⁻⁴ Pa, and then PCBBiF and ALD-MP00Q (produced by Analysis Atelier Corporation, material serial No. 1S20180314) were co-evaporated to a thickness of 10 nm such that PCBBiF:ALD-MP001Q=1:0.1 (weight ratio).

Then, the hole-transport layer 812 was formed over the hole-injection layer 811. The hole-transport layer 812 was formed to a thickness of 130 nm by evaporation using PCBBiF.

Next, the light-emitting layer 813 was formed over the hole-transport layer 812. As the host material, 9-[(3′-dibenzothiophen-4-yl)biphenyl-3-yl]naphtho[1′,2′: 4,5]furo[2,3-b]pyrazine (abbreviation: 9mDBtBPNfpr) and PCBBiF were used, and as the guest material (phosphorescent material), [Ir(dmdpbq)₂(dpm)] was used. Co-evaporation was performed so that the weight ratio was 9mDBtBPNfpr:PCBBiF:[Ir(dmdpbq)₂(dpm)]=0.7:0.3:X (X=0.01, 0.025, 0.05, or 0.1). That is, the guest material concentrations in the four devices in this example are 1.0 wt %, 2.4 wt %, 4.8 wt %, and 9.1 wt %. Note that the thickness was set to 10 nm.

Next, the electron-transport layer 814 was formed over the light-emitting layer 813.

The electron-transport layer 814 was formed by sequential evaporation such that the thickness of 9mDBtBPNfpr was 20 nm and the thickness of NBphen was 60 nm.

Then, the electron-injection layer 815 was formed over the electron-transport layer 814. The electron-injection layer 815 was formed to a thickness of 1 nm by evaporation using LiF.

After that, the second electrode 803 was formed over the electron-injection layer 815. The second electrode 803 was formed to a thickness of 200 nm by an evaporation method using aluminum. In this example, the second electrode 803 functions as a cathode.

Through the above steps, the light-emitting devices in each of which the EL layer 802 was provided between the pair of electrodes over the substrate 800 were fabricated. The hole-injection layer 811, the hole-transport layer 812, the light-emitting layer 813, the electron-transport layer 814, and the electron-injection layer 815 described in the above steps are functional layers forming the EL layer in one embodiment of the present invention. Furthermore, in all the evaporation steps in the above fabrication method, an evaporation method by a resistance-heating method was used.

The light-emitting device fabricated as described above was sealed using a different substrate (not illustrated). At the time of the sealing using the different substrate (not illustrated), the different substrate (not illustrated) on which an adhesive that is solidified by ultraviolet light was applied was fixed onto the substrate 800 in a glove box containing a nitrogen atmosphere, and the substrates were bonded to each other such that the adhesive was attached to the periphery of the light-emitting device formed over the substrate 800. At the time of the sealing, the adhesive was irradiated with 365-nm ultraviolet light at 6 J/cm² to be solidified, and the adhesive was subjected to heat treatment at 80° C. for one hour to be stabilized.

### <<Operation Characteristics of Light-Emitting Devices>>

Operation characteristics of the light-emitting devices fabricated in this example were measured. Note that the measurement was carried out at room temperature (in an atmosphere maintained at 25° C.). A spectroradiometer (SR-UL1R manufactured by TECHNOHOUSE CORPORATION) was used in measurement for a wavelength range of greater than or equal to 380 nm and less than or equal to 749 nm. A near-infrared spectroradiometer (SR-NIR manufactured by TOPCON TECHNOHOUSE CORPORATION) was used in measurement for a wavelength range of greater than or equal to 750 nm and less than or equal to 1030 nm.

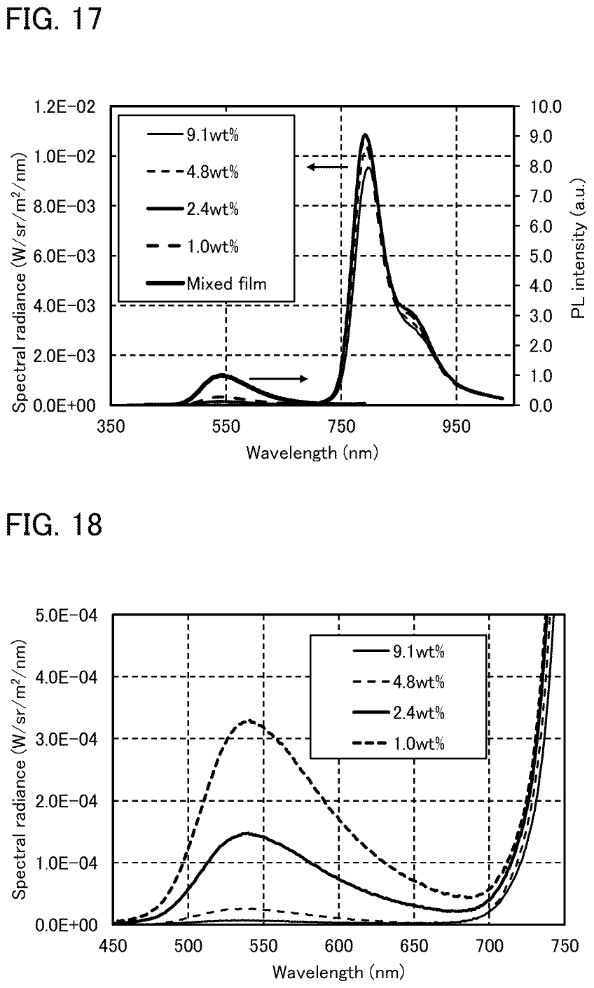

FIG. 17 and FIG. 18 show emission spectra obtained when current flowed through the four light-emitting devices at a current density of 5.0 mA/cm². Note that FIG. 18 is an enlarged graph of the visible light region.

FIG. 17 also shows the emission spectrum (PL spectrum) of a mixed film of the two host materials used for the light-emitting layer 813.

The mixed film was formed over a quartz substrate to have a thickness of 50 nm by co-evaporation of 9mDBtBPNfpr and PCBBiF in 9mDBtBPNfpr:PCBBiF=0.7:0.3 (weight ratio). Here, 9mDBtBPNfpr and PCBBiF form an exciplex in combination. The PL spectrum was measured at room temperature with a fluorophotometer (FS920, produced by Hamamatsu Photonics K.K.).

Table 5 shows the initial values of main characteristics of the devices of this example at a current of 0.2 mA (a current density of 5.0 mA/cm²). Note that the radiant flux and the external quantum efficiency were calculated using the radiance, assuming that the light-emitting devices had Lambertian light-distribution characteristics.

TABLE 5

| | | | Current | | | Luminance/ | Radiant | External quantum |
|---|---|---|---|---|---|---|---|---|
| Guest material | Voltage | Current | density | Luminance | Radiance | Radiance | flux | efficiency |
| concentration | (V) | (mA) | (mA/cm²) | (cd/m²) | (W/sr/m²) | (cd · sr/W) | (mW) | (%) |
| 9.1 wt % | 3.3 | 0.2 | 5.0 | 0.34 | 0.89 | 0.39 | 0.01 | 3.8 |
| 4.8 wt % | 3.3 | 0.2 | 5.0 | 1.2 | 0.95 | 1.3 | 0.01 | 4.0 |
| 2.4 wt % | 3.2 | 0.2 | 5.0 | 7.4 | 1.0 | 7.2 | 0.01 | 4.3 |
| 1.0 wt % | 3.2 | 0.2 | 5.0 | 17 | 0.99 | 17 | 0.01 | 4.1 |

As shown in FIG. 17, each of the light-emitting devices emitted near-infrared light originating from [Ir(dmdpbq)₂(dpm)] contained in the light-emitting layer 813.

As shown in FIG. 17 and FIG. 18, it was confirmed that the emission spectrum of each light-emitting device had a relatively high emission peak in the visible wavelength range. It was found that light emitted by each light-emitting device included light in a wavelength range of a high luminosity factor of visible light. In other words, visible light emitted by the light-emitting devices of this example is easily seen.

The emission peak wavelength in the PL spectrum of the mixed film shown in FIG. 17 was 542 nm (2.29 eV), which was a value close to the energy of the difference (2.31 eV) between the LUMO level (−3.05 eV) of 9mDBtBPNfpr and the HOMO level (−5.36 eV) of PCBBiF, showing that light emission originating from the exciplex was obtained.

The emission peak wavelength in the visible light region in each of the light-emitting devices was close to the emission peak wavelength in the PL spectrum of the mixed film, indicating that the visible light emission observed in the light-emitting devices of this example was light emission originating from the exciplex formed by the two host materials.

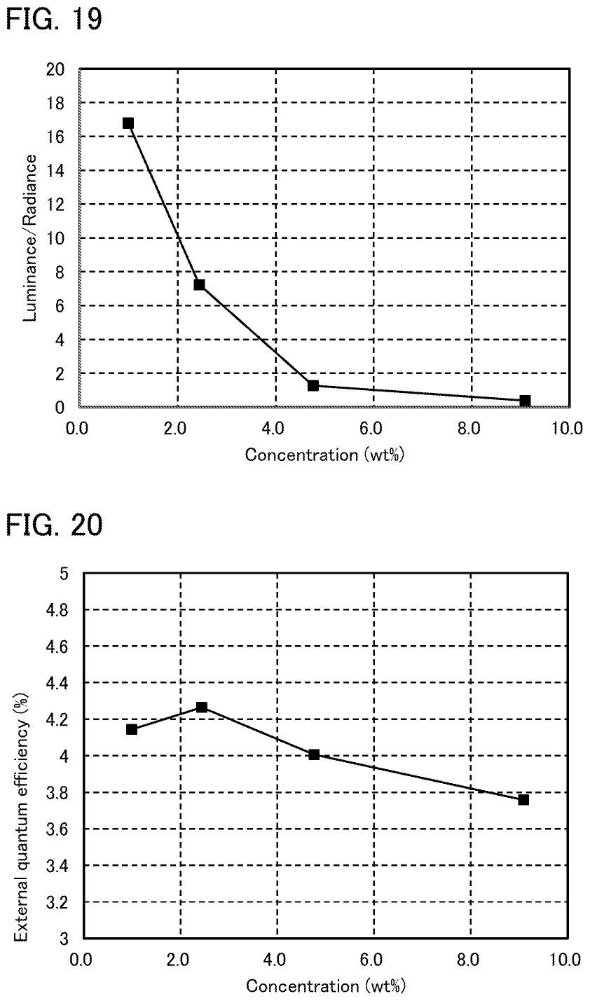

Here, FIG. 19 shows the relationship between the guest material concentration and the luminance/radiance of the light-emitting device. FIG. 20 shows the relationship between the guest material concentration and the external quantum efficiency of the light-emitting device. Note that the external quantum efficiency of the light-emitting device of this example was calculated from measurement results of a wavelength range of greater than or equal to 600 nm and less than or equal to 1030 nm. The range is a region having longer wavelengths than the emission peak in the visible light region of the light-emitting device in this example. The external quantum efficiency can be regarded as external quantum efficiency calculated mainly from near-infrared light of the light-emitting device in this example.

As shown in FIG. 19, it was found that the luminance/radiance of the light-emitting device became larger as the guest material concentration became lower. That is, the emission intensity of visible light became higher with respect to the emission intensity of near-infrared light as the guest material concentration became lower.

In the case where visible light emission originating from the exciplex is intense, energy is presumably not sufficiently transferred from the exciplex to the guest material. However, in the three light-emitting devices with the guest material concentrations of 2.4 wt %, 4.8 wt %, and 9.1 wt %, the external quantum efficiency became high when the guest material became low as shown in FIG. 20. This is presumably because concentration quenching of the guest material was reduced owing to the low guest material concentration.

The above results show that it is possible to achieve a light-emitting device in which visible light is easy to see and which has high emission efficiency of near-infrared light by lowering the guest material concentration.

### Reference Example

A method for synthesizing bis{4,6-dimethyl-2-[3-(3,5-dimethylphenyl)-2-benzo[g]quinoxalinyl-κN]phenyl-κC}(2,2,6,6-tetramethyl-3,5-heptanedionato-κ²O,O′)iridium(III) (abbreviation: [Ir(dmdpbq)₂(dpm)]) that was used in Example 1 above will be specifically described. The structure of [Ir(dmdpbq)₂(dpm)] is shown below.

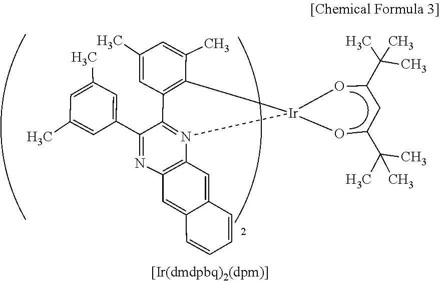

### Step 1; Synthesis of 2,3-bis-(3,5-dimethylphenyl)-2-benzo[g]quinoxaline (Abbreviation: Hdmdpbq)

First, in Step 1, Hdmdpbq was synthesized. Into a three-neck flask equipped with a reflux pipe, 3.20 g of 3,3′,5,5′-tetramethylbenzyl, 1.97 g of 2,3-diaminonaphthalene, and 60 mL of ethanol were put, the air in the flask was replaced with nitrogen, and then the mixture was stirred at 90° C. for 7.5 hours. After a predetermined time elapsed, the solvent was distilled off. Then, purification by silica gel column chromatography using toluene as a developing solvent was performed, whereby the target substance was obtained (a yellow solid, yield: 3.73 g, percent yield: 79%). The synthesis scheme of Step 1 is shown in (a-1).

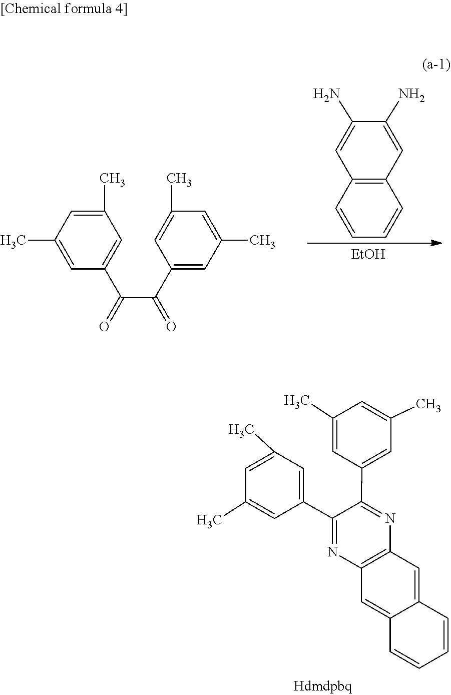

Analysis results by nuclear magnetic resonance spectroscopy (¹H-NMR) of the yellow solid obtained in Step 1 are shown below. The analysis results revealed that Hdmdpbq was obtained.

Given below is ¹H NMR data of the obtained substance.

¹H-NMR. δ (CD₂Cl₂): 2.28 (s, 12H), 7.01 (s, 2H), 7.16 (s, 4H), 7.56-7.58 (m, 2H), 8.11-8.13 (m, 2H), 8.74 (s, 2H).

### Step 2; Synthesis of di-μ-chloro-tetrakis{4,6-dimethyl-2-[3-(3,5-dimethylphenyl)-2-benzo[g]quinoxalinyl-κN]phenyl-κC}diiridium(III) (Abbreviation: [Ir(dmdpbq)₂Cl]₂)

Next, in Step 2, [Ir(dmdpbq)₂Cl]₂ was synthesized. Into a recovery flask equipped with a reflux pipe, 15 mL of 2-ethoxyethanol, 5 mL of water, 1.81 g of Hdmdpbq obtained in Step 1, and 0.66 g of iridium chloride hydrate (IrCl₃.H₂O) (produced by Furuya Metal Co., Ltd.) were put, and the air in the flask was replaced with argon. Then, microwave irradiation (2.45 GHz, 100 W) was performed for two hours to cause reaction. After a predetermined time elapsed, the obtained residue was suction-filtered and washed with methanol, whereby the target substance was obtained (a black solid, yield: 1.76 g, percent yield: 81%). The synthesis scheme of Step 2 is shown in (a-2).

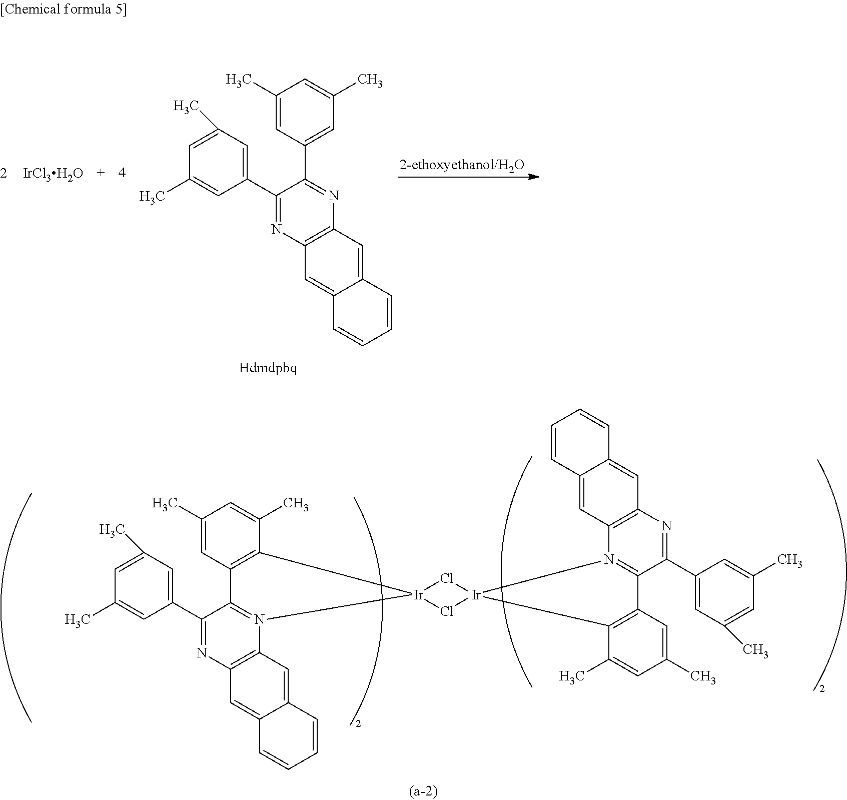

### Step 3; Synthesis of [Ir(dmdpbq)₂(dpm)]

Then, in Step 3, [Ir(dmdpbq)₂(dpm)] was synthesized. Into a recovery flask equipped with a reflux pipe, 20 mL of 2-ethoxyethanol, 1.75 g of [Ir(dmdpbq)₂Cl]₂ obtained in Step 2, 0.50 g of dipivaloylmethane (abbreviation: Hdpm), and 0.95 g of sodium carbonate were put, and the air in the flask was replaced with argon. Then, microwave irradiation (2.45 GHz, 100 W) was performed for three hours. The obtained residue was suction-filtered with methanol and then washed with water and methanol. The obtained solid was purified by silica gel column chromatography using dichloromethane as a developing solvent, and then recrystallization was performed with a mixed solvent of dichloromethane and methanol, whereby the target substance was obtained (a dark green solid, yield: 0.42 g, percent yield: 21%). With a train sublimation method, 0.41 g of the obtained dark green solid was purified by sublimation. The conditions of the sublimation purification were such that the dark green solid was heated under a pressure of 2.7 Pa at 300° C. while the argon gas flowed at a flow rate of 10.5 mL/min. After the sublimation purification, a dark green solid was obtained in a percent yield of 78%. The synthesis scheme of Step 3 is shown in (a-3).

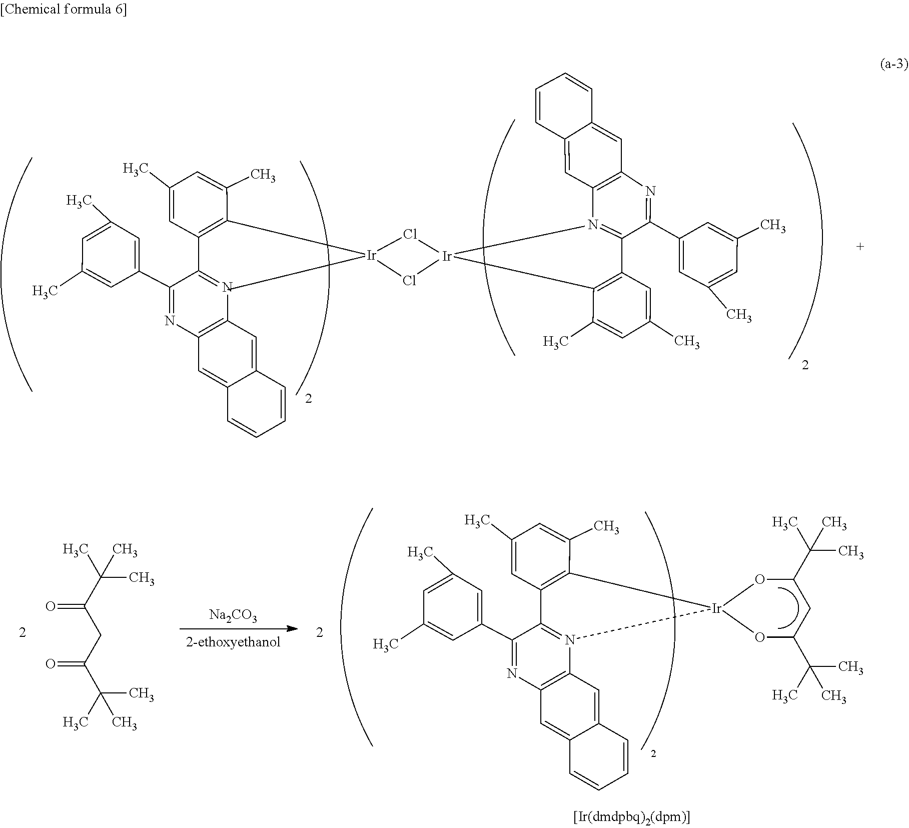

Analysis results by nuclear magnetic resonance spectroscopy (¹H-NMR) of the dark green solid obtained in Step 3 are shown below. The analysis results revealed that [Ir(dmdpbq)₂(dpm)] was obtained.

¹H-NMR. δ (CD₂Cl₂): 0.75 (s, 18H), 0.97 (s, 6H), 2.01 (s, 6H), 2.52 (s, 12H), 4.86 (s, 1H), 6.39 (s, 2H), 7.15 (s, 2H), 7.31 (s, 2H), 7.44-7.51 (m, 4H), 7.80 (d, 2H), 7.86 (s, 4H), 8.04 (d, 2H), 8.42 (s, 2H), 8.58 (s, 2H).

### REFERENCE NUMERALS

101: first electrode, 102: second electrode, 103: EL layer, 103a: EL layer, 103b: EL layer, 104: charge-generation layer, 111: hole-injection layer, 112: hole-transport layer, 113: light-emitting layer, 114: electron-transport layer, 115: electron-injection layer, 301: substrate, 302: pixel portion, 303: circuit portion, 304a: circuit portion, 304b: circuit portion, 305: sealant, 306: substrate, 307: wiring, 308: FPC, 309: transistor, 310: transistor, 311: transistor, 312: transistor, 313: first electrode, 314: insulating layer, 315: EL layer, 316: second electrode, 317: organic EL device, 318: space, 401: first electrode, 402: EL layer, 403: second electrode, 405: insulating layer, 406: conductive layer, 407: adhesive layer, 416: conductive layer, 420: substrate, 422: adhesive layer, 423: barrier layer, 424: insulating layer, 450: organic EL device, 490a: substrate, 490b: substrate, 490c: barrier layer, 800: substrate, 801: first electrode, 802: EL layer, 803: second electrode, 811: hole-injection layer, 812: hole-transport layer, 813: light-emitting layer, 814: electron-transport layer, 815: electron-injection layer, 911: housing, 912: light source, 913: sensing stage, 914: imaging device, 915: light-emitting portion, 916: light-emitting portion, 917: light-emitting portion, 921: housing, 922: operation button, 923: sensing portion, 924: light source, 925: imaging device, 931: housing, 932: operation panel, 933: transport mechanism, 934: monitor, 935: sensing unit, 936: test specimen, 937: imaging device, 938: light source, 981: housing, 982: display portion, 983: operation button, 984: external connection port, 985: speaker, 986: microphone, 987: camera, 988: camera,

1. A light-emitting device comprising:
a light-emitting layer,
wherein the light-emitting layer comprises a light-emitting organic compound and a host material,
wherein a maximum peak wavelength in an emission spectrum of the light-emitting device is greater than or equal to 750 nm and less than or equal to 900 nm,
wherein the emission spectrum further comprises a peak at a wavelength greater than or equal to 450 nm and less than or equal to 650 nm, and
wherein a luminance A [cd/m²] and a radiance B [W/sr/m²] satisfy A/B>0.1 [cd·sr/W].

2. The light-emitting device according to claim 1,
wherein a difference between a HOMO level and a LUMO level of the host material is greater than or equal to 1.90 eV and less than or equal to 2.75 eV.

3. The light-emitting device according to claim 1,
wherein a difference between a singlet excitation energy level and a triplet excitation energy level of the host material is less than or equal to 0.2 eV.

4. The light-emitting device according to claim 1,
wherein the host material exhibits thermally activated delayed fluorescence.

5. The light-emitting device according to claim 1,
wherein the host material comprises a first organic compound and a second organic compound,
wherein a HOMO level of the first organic compound is higher than a HOMO level of the second organic compound, and
wherein a difference between the HOMO level of the first organic compound and a LUMO level of the second organic compound is greater than or equal to 1.90 eV and less than or equal to 2.75 eV.

6. The light-emitting device according to claim 5,
wherein the first organic compound and the second organic compound form an exciplex.

7. The light-emitting device according to claim 6,
wherein the exciplex exhibits thermally activated delayed fluorescence.

8. A light-emitting device comprising:
a light-emitting layer,
wherein the light-emitting layer comprises a light-emitting organic compound and a host material,
wherein a maximum peak wavelength in an emission spectrum of the light-emitting device is greater than or equal to 750 nm and less than or equal to 900 nm,
wherein an energy of a maximum peak in a PL spectrum of the host material is higher than an energy of a peak of a lowest-energy-side absorption band in an absorption spectrum of the light-emitting organic compound by 0.20 eV or more, and
wherein the light-emitting device is configured to emit both visible light and near-infrared light.

9. The light-emitting device according to claim 8,
wherein the energy of the maximum peak in the PL spectrum is higher than an energy of a lowest-energy-side absorption edge in the absorption spectrum by 0.30 eV or more.

10. A light-emitting device comprising:
a light-emitting layer,
wherein the light-emitting layer comprises a light-emitting organic compound and a host material,
wherein an emission spectrum of the light-emitting device comprises a first peak at a wavelength greater than or equal to 750 nm and less than or equal to 900 nm and comprises a second peak at a wavelength greater than or equal to 450 nm and less than or equal to 650 nm,
wherein the first peak has higher intensity than the second peak, and
wherein an energy of the second peak is higher than an energy of a peak of a lowest-energy-side absorption band in an absorption spectrum of the light-emitting organic compound by 0.35 eV or more.

11. The light-emitting device according to claim 10,
wherein the intensity of the first peak is greater than or equal to 10 times and less than or equal to 10000 times the intensity of the second peak.

12. The light-emitting device according to claim 8,
wherein a difference between a HOMO level and a LUMO level of the host material is greater than or equal to 1.90 eV and less than or equal to 2.75 eV.

13. The light-emitting device according to claim 8,
wherein a difference between a singlet excitation energy level and a triplet excitation energy level of the host material is less than or equal to 0.2 eV.

14. The light-emitting device according to claim 8,
wherein the host material exhibits thermally activated delayed fluorescence.

15. The light-emitting device according to claim 8,
wherein the host material comprises a first organic compound and a second organic compound, and
wherein the first organic compound and the second organic compound form an exciplex.

16. (canceled)

17. The light-emitting device according to claim 10,
wherein the host material comprises a first organic compound and a second organic compound, and
wherein the first organic compound and the second organic compound form an exciplex.

18. (canceled)

19. The light-emitting device according to claim 15,
wherein a HOMO level of the first organic compound is higher than a HOMO level of the second organic compound, and
wherein a difference between the HOMO level of the first organic compound and a LUMO level of the second organic compound is greater than or equal to 1.90 eV and less than or equal to 2.75 eV.

20. The light-emitting device according to claim 1,
wherein a concentration of the light-emitting organic compound in the light-emitting layer is greater than or equal to 0.1 wt % and less than or equal to 10 wt %.

21. The light-emitting device according to claim 1,
wherein a rising wavelength of a maximum peak on a short wavelength side in the emission spectrum is greater than or equal to 650 nm.

22. The light-emitting device according to claim 1,
wherein a rising wavelength of a maximum peak on a short wavelength side in a PL spectrum of the light-emitting organic compound in a solution is greater than or equal to 650 nm.

23. The light-emitting device according to claim 1,
wherein an external quantum efficiency is greater than or equal to 1%.

24. The light-emitting device according to claim 1,
wherein CIE chromaticity coordinates (x1, y1) at a first radiance and CIE chromaticity coordinates (x2, y2) at a second radiance satisfy one or both of x1>x2 and y1>y2, and
wherein the first radiance is lower than the second radiance.

25. A light-emitting apparatus comprising:
the light-emitting device according to claim 1; and
one or both of a transistor and a substrate.

26. A light-emitting module comprising:
the light-emitting apparatus according to claim 25; and
one or both of a connector and an integrated circuit.

27. An electronic device comprising:
the light-emitting module according to claim 26; and
at least one of an antenna, a battery, a housing, a camera, a speaker, a microphone, and an operation button.

28. A lighting device comprising:
the light-emitting apparatus according to claim 25; and
at least one of a housing, a cover, and a supporting base.

29. The light-emitting device according to claim 10,
wherein a difference between a HOMO level and a LUMO level of the host material is greater than or equal to 1.90 eV and less than or equal to 2.75 eV.

30. The light-emitting device according to claim 17,
wherein a HOMO level of the first organic compound is higher than a HOMO level of the second organic compound, and
wherein a difference between the HOMO level of the first organic compound and a LUMO level of the second organic compound is greater than or equal to 1.90 eV and less than or equal to 2.75 eV.

31. The light-emitting device according to claim 8,
wherein a rising wavelength of a maximum peak on a short wavelength side in the emission spectrum is greater than or equal to 650 nm.

32. The light-emitting device according to claim 10,
wherein a rising wavelength of a maximum peak on a short wavelength side in the emission spectrum is greater than or equal to 650 nm.
